(19) United States
(12) Patent Application Publication
(10) Pub. No.: US 2024/0274647 A1
(43) Pub. Date: Aug. 15, 2024

(54) LIGHT EMITTING DEVICE

(71) Applicant: Japan Display Inc., Tokyo (JP)

(72) Inventors: Masumi NISHIMURA, Tokyo (JP); Shinichiro OKA, Tokyo (JP); Hayata AOKI, Tokyo (JP); Hiroumi KINJO, Tokyo (JP)

(73) Assignee: Japan Display Inc., Tokyo (JP)

(21) Appl. No.: 18/585,506

(22) Filed: Feb. 23, 2024

Related U.S. Application Data
(63) Continuation of application No. PCT/JP2022/029676, filed on Aug. 2, 2022.

(30) Foreign Application Priority Data
Aug. 24, 2021 (JP) 2021-136564

(51) Int. Cl. H01L 27/15; H01L 25/075; H01L 33/00; H01L 33/20; H01L 33/32

(52) U.S. Cl. CPC H01L 27/156; H01L 33/20; H01L 33/32; H01L 25/0753; H01L 33/007

(57) ABSTRACT

A light emitting device includes a plurality of pixels arranged in a matrix in a first direction and in a second direction orthogonal to the first direction. Each of the plurality of pixels arranged in a matrix includes a substrate, a conductive alignment layer over the substrate, a first nitride semiconductor layer over the conductive alignment layer, a second nitride semiconductor layer comprising a light emitting layer, over the first nitride semiconductor layer, and an electrode layer over the second nitride semiconductor layer. The first nitride semiconductor layer and the second nitride semiconductor layer are provided in an island shape. The plurality of pixels arranged in a matrix commonly includes the substrate.

### CROSS-REFERENCE TO RELATED APPLICATIONS

This application is a Continuation of International Patent Application No. PCT/JP2022/029676, filed on Aug. 2, 2022, which claims the benefit of priority to Japanese Patent Application No. 2021-136564, filed on Aug. 24, 2021, the entire contents of which are incorporated herein by reference.

### FIELD

An embodiment of the present invention relates to a light emitting device including a nitride semiconductor. Further, an embodiment of the present invention relates to a light emitting device forming substrate on which a plurality of light emitting devices including a nitride semiconductor are formed.

### BACKGROUND

A nitride semiconductor such as gallium nitride (GaN) is characterized as a direct bandgap semiconductor with a large bandgap. The characteristics of gallium nitride are utilized, and a light emitting diode (LED) using gallium nitride has already been in practical use. A gallium nitride film for an LED is generally formed on a sapphire substrate at a high temperature of 800 degrees to 1000 degrees using MOCVD (Metal Organic Chemical Vapor Deposition) or HVPE (Hydride Vapor Phase Epitaxy).

In recent years, the development of a so-called micro LED display device or a mini-LED display device in which minute micro LEDs are mounted in pixels on a circuit substrate is proceeding as a next-generation display device. The micro LED display device or the mini LED display device has high efficiency, high brightness and high reliability. Such a micro LED display device or a mini-LED display device is manufactured by transferring a LED chip to a backplane on which a transistor using an oxide semiconductor or low-temperature polysilicon is formed (for example, see U.S. Pat. No. 8,791,474).

### SUMMARY

A light emitting device according to an embodiment of the present invention includes a plurality of pixels arranged in a matrix in a first direction and in a second direction orthogonal to the first direction. Each of the plurality of pixels arranged in a matrix includes a substrate, a conductive alignment layer over the substrate, a first nitride semiconductor layer over the conductive alignment layer, a second nitride semiconductor layer including a light emitting layer, over the first nitride semiconductor layer, and an electrode layer over the second nitride semiconductor layer. The first nitride semiconductor layer and the second nitride semiconductor layer are provided in an island shape. The plurality of pixels arranged in a matrix commonly includes the substrate.

A light emitting device according to an embodiment of the present invention includes a plurality of pixels arranged in a matrix in a first direction and in a second direction orthogonal to the first direction. Each of the plurality of pixels arranged in a matrix includes a substrate, an insulating alignment layer over the substrate, a first nitride semiconductor layer over the insulating alignment layer, a second nitride semiconductor layer including a light emitting layer, over the first nitride semiconductor layer, a first electrode layer over the first nitride semiconductor layer, and a second electrode layer over the second nitride semiconductor layer. The first nitride semiconductor layer and the second nitride semiconductor layer are provided in an island shape. The plurality of pixels arranged in a matrix commonly comprises the substrate.

### BRIEF DESCRIPTION OF DRAWINGS

FIG. 1 is a schematic diagram showing a configuration of a light emitting device according to an embodiment of the present invention (First Embodiment).

FIG. 2 is a schematic cross-sectional view showing a configuration of a light emitting device according to an embodiment of the present invention (First Embodiment).

FIG. 3 is a schematic plan view showing a configuration of a light emitting device according to an embodiment of the present invention (First Embodiment).

FIG. 4A is a schematic cross-sectional view showing a method for manufacturing a light emitting device according to an embodiment of the present invention (First Embodiment).

FIG. 4B is a schematic cross-sectional view showing a method for manufacturing a light emitting device according to an embodiment of the present invention (First Embodiment).

FIG. 4C is a schematic cross-sectional view showing a method for manufacturing a light emitting device according to an embodiment of the present invention (First Embodiment).

FIG. 4D is a schematic cross-sectional view showing a method for manufacturing a light emitting device according to an embodiment of the present invention (First Embodiment).

FIG. 4E is a schematic cross-sectional view showing a method for manufacturing a light emitting device according to an embodiment of the present invention (First Embodiment).

FIG. 4F is a schematic cross-sectional view showing a method for manufacturing a light emitting device according to an embodiment of the present invention (First Embodiment).

FIG. 5 is a schematic cross-sectional view showing a configuration of a light emitting device according to an embodiment of the present invention (Modification 1 of First Embodiment).

FIG. 6 is a schematic plan view showing a configuration of a light emitting device according to an embodiment of the present invention (Modification 1 of First Embodiment).

FIG. 7 is a schematic cross-sectional view showing a configuration of a light emitting device according to an embodiment of the present invention (Modification 2 of First Embodiment).

FIG. 8 is a schematic cross-sectional view showing a configuration of a light emitting device according to an embodiment of the present invention (Modification 3 of First Embodiment).

FIG. 9 is a schematic cross-sectional view showing a configuration of a light emitting device according to an embodiment of the present invention (Second Embodiment).

FIG. 10 is a schematic plan view showing a configuration of a light emitting device according to an embodiment of the present invention (Second Embodiment).

FIG. 11 is a schematic cross-sectional view showing a configuration of a light emitting device according to an embodiment of the present invention (Modification 1 of Second Embodiment).

FIG. 12 is a schematic cross-sectional view showing a configuration of a light emitting device according to an embodiment of the present invention (Modification 2 of Second Embodiment).

FIG. 13 is a schematic cross-sectional view showing a configuration of a light emitting device according to an embodiment (Modification 3 of Second Embodiment) of the present invention.

FIG. 14 is a schematic cross-sectional view showing a configuration of a light emitting device according to an embodiment of the present invention (Modification 4 of Second Embodiment).

FIG. 15 is a schematic plan view showing a configuration of a light emitting device according to an embodiment of the present invention (Modification 4 of Second Embodiment).

FIG. 16 is a schematic cross-sectional view showing a configuration of a light emitting device according to an embodiment of the present invention (Modification 5 of Second Embodiment).

FIG. 17 is a schematic plan view showing a configuration of a light emitting device according to an embodiment of the present invention (Modification 5 of Second Embodiment).

FIG. 18 is a schematic cross-sectional view showing a configuration of a light emitting device according to an embodiment of the present invention

(Third Embodiment).

FIG. 19 is a schematic cross-sectional view showing a configuration of a light emitting device according to an embodiment of the present invention (Third Embodiment).

FIG. 20 is a schematic cross-sectional view showing a configuration of a light emitting device according to an embodiment of the present invention (Modification 1 of Third Embodiment).

FIG. 21 is a schematic cross-sectional view showing a configuration of a light emitting device according to an embodiment of the present invention (Modification 1 of Third Embodiment).

FIG. 22 is a schematic cross-sectional view showing a configuration of a light emitting device according to an embodiment of the present invention (Modification 2 of Third Embodiment).

FIG. 23 is a schematic cross-sectional view showing a configuration of a light emitting device according to an embodiment of the present invention (Modification 3 of Third Embodiment).

FIG. 24 is a schematic cross-sectional view showing a configuration of a light emitting device according to an embodiment of the present invention (Fourth Embodiment).

FIG . 25 is a schematic cross-sectional view showing a configuration of a light emitting device according to an embodiment of the present invention (Modification 1 of Fourth Embodiment).

FIG. 26 is a schematic cross-sectional view showing a configuration of a light emitting device according to an embodiment of the present invention (Fifth Embodiment).

FIG. 27A is a schematic cross-sectional view showing a method for manufacturing a light emitting device according to an embodiment of the present invention (Fifth Embodiment).

FIG. 27B is a schematic cross-sectional view showing a method for manufacturing a light emitting device according to an embodiment of the present invention (Fifth Embodiment).

FIG. 27C is a schematic cross-sectional view showing a method for manufacturing a light emitting device according to an embodiment of the present invention (Fifth Embodiment).

FIG. 27D is a schematic cross-sectional view showing a method for manufacturing a light emitting device according to an embodiment of the present invention (Fifth Embodiment).

FIG. 27E is a schematic cross-sectional view showing a method for manufacturing a light emitting device according to an embodiment of the present invention (Fifth Embodiment).

FIG. 27F is a schematic cross-sectional view showing a method for manufacturing a light emitting device according to an embodiment of the present invention (Fifth Embodiment).

FIG. 27G is a schematic cross-sectional view showing a method for manufacturing a light emitting device according to an embodiment of the present invention (Fifth Embodiment).

FIG. 27H is a schematic cross-sectional view showing a method for manufacturing a light emitting device according to an embodiment of the present invention (Fifth Embodiment).

FIG. 28 is a schematic cross-sectional view showing a configuration of a light emitting device according to an embodiment of the present invention (Modification 1 of Fifth Embodiment).

FIG. 29 is a schematic plan view showing a configuration of a light emitting device according to an embodiment of the present invention (Modification 1 of Fifth Embodiment).

FIG. 30 is a schematic cross-sectional view showing a configuration of a light emitting device according to an embodiment of the present invention (Modification 2 of Fifth Embodiment).

FIG. 31 is a schematic cross-sectional view showing a configuration of a light emitting device according to an embodiment of the present invention (Modification 3 of Fifth Embodiment).

FIG. 32 is a schematic cross-sectional view showing a configuration of a light emitting device according to an embodiment of the present invention (Modification 4 of Fifth Embodiment).

FIG. 33 is a schematic plan view showing a configuration of a light emitting device according to an embodiment of the present invention (Modification 4 of Fifth Embodiment).

FIG. 34 is a schematic cross-sectional view showing a configuration of a light emitting device according to an embodiment of the present invention (Sixth Embodiment).

FIG. 35 is a schematic plan view showing a configuration of a light emitting device according to an embodiment of the present invention (Sixth Embodiment).

FIG. 36 is a schematic cross-sectional view showing a configuration of a light emitting device according to an embodiment of the present invention (Modification 1 of Sixth Embodiment).

FIG. 37 is a schematic cross-sectional view showing the configuration of a light emitting device according to an embodiment of the present invention (Modification 2 of Sixth Embodiment).

FIG. 38 is a schematic cross-sectional view showing a configuration of a light emitting device according to an embodiment of the present invention (Modification 3 of Sixth Embodiment).

FIG. 39 is a schematic cross-sectional view showing a configuration of a light emitting device according to an embodiment of the present invention (Seventh Embodiment). FIG. 40 is a schematic cross-sectional view showing a configuration of a light emitting device according to an embodiment of the present invention (Modification 1 of Seventh Embodiment).

FIG. 41 is a schematic cross-sectional view showing a configuration of a light emitting device according to an embodiment of the present invention (Modification 2 of Seventh Embodiment).

FIG. 42 is a schematic cross-sectional view showing a configuration of a light emitting device according to an embodiment of the present invention (Modification 3 of Seventh Embodiment).

FIG. 43 is a schematic cross-sectional view showing a configuration of a light emitting device according to an embodiment of the present invention (Eighth Embodiment).

FIG. 44 is a schematic cross-sectional view showing a configuration of a light emitting device according to an embodiment of the present invention (Modification 1 of t Eighth Embodiment).

FIG. 45 is a schematic diagram showing a configuration of a light emitting device forming substrate according to an embodiment of the present invention (Ninth Embodiment).

### DESCRIPTION OF EMBODIMENTS

The method for manufacturing a micro LED display device by transferring LED chips has a high manufacturing cost, and it is difficult to manufacture the micro LED display device at low cost. On the other hand, if LEDs can be formed on a large-area substrate such as an amorphous glass substrate, the manufacturing cost can be reduced. However, as described above, since a gallium nitride film is formed on a sapphire substrate at a high temperature, it is difficult to form a gallium nitride film directly on an amorphous glass substrate.

In view of the above problem, an embodiment of the present invention can provide a light emitting device including a nitride semiconductor layer formed on a large-area substrate such as an amorphous glass substrate. Further, an embodiment of the present invention can provide a light emitting device forming substrate on which a plurality of light emitting devices including a nitride semiconductor layer are formed.

Hereinafter, each of the embodiments of the present invention are described with reference to the drawings. Each of the embodiments is merely an example, and a person skilled in the art could easily conceive of the invention by appropriately changing the embodiment while maintaining the gist of the invention, and such changes are naturally included in the scope of the invention. For the sake of clarity of the description, the drawings may be schematically represented with respect to the widths, thicknesses, shapes, and the like of the respective portions in comparison with actual embodiments.

However, the illustrated shapes are merely examples and are not intended to limit the interpretation of the present invention.

In the present specification, the expressions “a includes A, B or C”, “a includes any of A, B and C”, and “a includes one selected from the group consisting of A, B and C” do not exclude the case where a includes a plurality of combinations of A to C unless otherwise specified. Further, these expressions do not exclude the case where a includes other elements.

In the present specification, although the phrase “above” or “above direction” or “below” or “below direction” is used for convenience of explanation, in principle, the direction from a substrate toward a structure is referred to as “above” or “above direction” with reference to a substrate in which the structure is formed. Conversely, the direction from the structure to the substrate is referred to as “below” or “below direction”. Therefore, in the expression of a structure over a substrate, one surface of the structure in the direction facing the substrate is the bottom surface of the structure and the other surface is the upper surface of the structure. In addition, the expression of a structure over a substrate only explains the vertical relationship between the substrate and the structure, and another member may be placed between the substrate and the structure. Furthermore, the terms “above” or “above direction” or “below” or “below direction” mean the order of stacked layers in the structure in which a plurality of layers are stacked, and may not be related to the position in which layers overlap in a plan view.

In the specification, terms such as “first”, “second”, or “third” attached to each configuration are convenient terms used to distinguish each configuration, and have no further meaning unless otherwise explained.

In the specification and the drawings, the same reference numerals may be used when multiple configurations are identical or similar in general, and reference numerals with a lower or upper case letter of the alphabet may be used when the multiple configurations are distinguished. Further, reference numerals with a hyphen and a natural number may be used when multiple portions of one configuration are distinguished.

The following embodiments can be combined with each other as long as there is no technical contradiction.

### First Embodiment

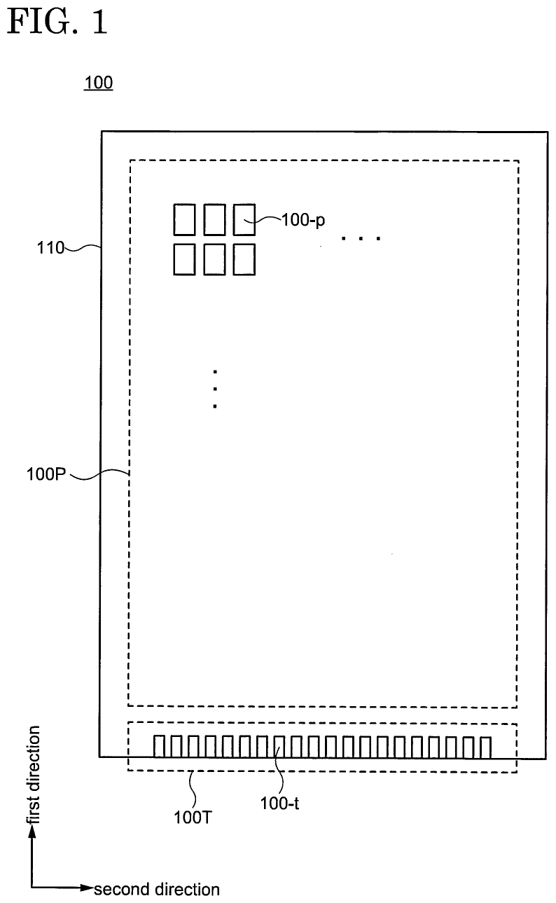

A light emitting device 100 according to an embodiment of the present invention is described with reference to FIG. 1 to FIG. 4F.

### 1. Configuration of Light Emitting Device 100

FIG. 1 is a schematic diagram showing a configuration of a light emitting device 100 according to an embodiment of the present invention. In the light emitting device 100, a pixel portion 100P and a terminal portion 100T are formed on a substrate 110. The pixel portion 100P is formed at the center of the substrate 110, and the terminal portion 100T is formed at the end of the substrate 110. The pixel section 100P includes a plurality of pixels 100-p arranged in a first direction (hereinafter, referred to as a column) and a second direction (hereinafter, referred as a row) orthogonal to (intersecting) the first direction. Although the details are described later, a light emitting diode (LED) is formed in each of the plurality of pixels 100-p. The terminal portion 100T includes a plurality of terminals 100-t. A power supply line is connected to each of the plurality of terminals 100-t, and can apply a voltage (supply current) to the LED in the pixel 100-p. In addition, although the details are not shown here, a transistor may be provided in the pixel 100-p, and the ON or OFF of the LED may be controlled by the transistor.

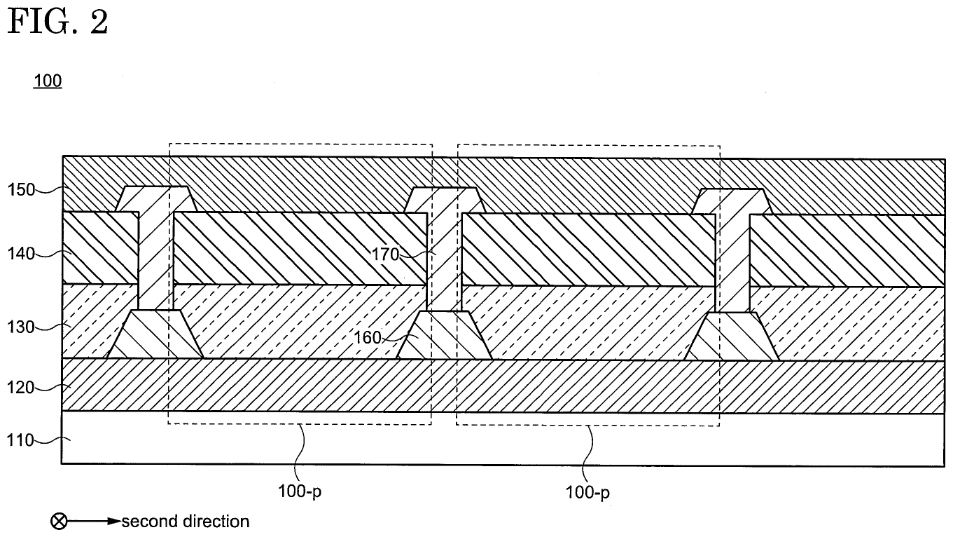

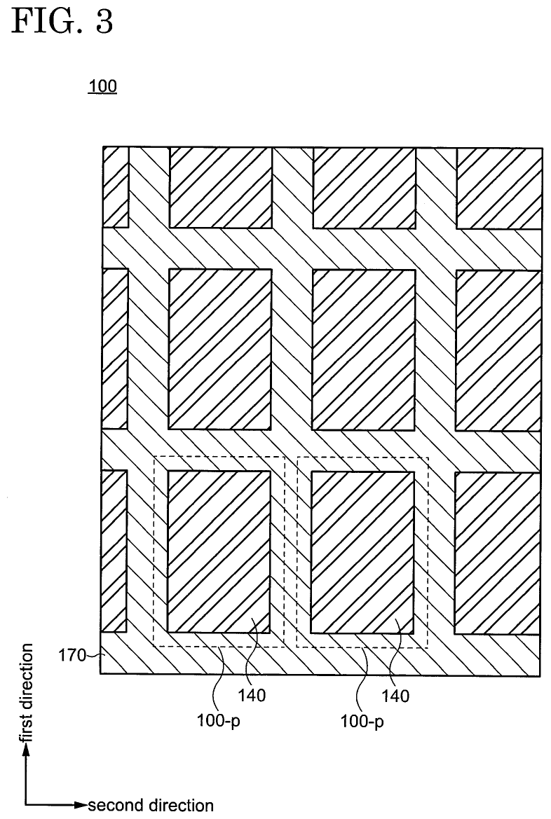

FIG. 2 is a schematic cross-sectional view showing a configuration of the light emitting device 100 according to an embodiment of the present invention. Specifically, FIG. 2 is a cross-sectional view of the pixel 100-p. Further, FIG. 3 is a schematic plan view showing a configuration of the light emitting device 100 according to an embodiment of the present invention.

As shown in FIG. 2, the light emitting device 100 includes a substrate 110, a conductive alignment layer 120, a first nitride semiconductor layer 130, a second nitride semiconductor layer 140, an electrode layer 150, a first rib 160, and a second rib 170. In FIG. 3, for convenience of explanation, the second nitride semiconductor layer 140 and the electrode layer 150 on the second rib 170 are omitted.

The conductive alignment layer 120 is provided on the substrate 110. Further, the conductive alignment layer 120 is provided commonly in the plurality of pixels 100-p arranged in a matrix.

The first nitride semiconductor layer 130 and the second nitride semiconductor layer 140 are provided over the conductive alignment layer 120 in this order. Further, each of the first nitride semiconductor layer 130 and the second nitride semiconductor layer 140 is provided in an island shape in each of the plurality of pixels 100-p arranged in a matrix.

The electrode layer 150 is provided on the second nitride semiconductor layer 140 and second rib 170 so as to cover the second nitride semiconductor layer 140. Further, the electrode layer 150 is provided commonly in the plurality of pixels 100-p arranged in a matrix.

The first rib 160 is provided on the conductive alignment layer 120 in a grid pattern. Further, the second rib 170 is provided on the first rib 160 in a grid pattern. The plurality of pixels 100-p are partitioned by the first rib 160 and the second rib 170.

The stack of the first rib 160 and the second rib 170 includes an opening through which the conductive alignment layer 120 is exposed. Further, the stack of the first nitride semiconductor layer 130 and the second nitride semiconductor layer 140 are formed in the opening of the stack of the first rib 160 and the second rib 170 so as to cover the conductive alignment layer 120. That is, a plurality of the stacks of the first nitride semiconductor layer 130 and second nitride semiconductor layer 140 is separated by the first rib 160 and the second rib 170.

In the following description, the details of each component of the light emitting device 100 is described.

The substrate 110 is a support substrate for the LED. Although the details are described later, each of the first nitride semiconductor layer 130 and the second nitride semiconductor layer 140 in the light emitting device 100 is formed by sputtering. Therefore, it is sufficient that the substrate 110 has a heat resistance of, for example, about 600 degrees. For example, an amorphous glass substrate can be used as the substrate 110. Further, a resin substrate such as a polyimide substrate, an acrylic substrate, a siloxane substrate, or a fluororesin substrate can also be used as the substrate 110.

The amorphous glass substrate or the resin substrate is a substrate that can have a large area. In addition, a polycrystalline substrate can also be used as the substrate 110. The polycrystalline substrate can have a larger area than the sapphire substrate that is used in general film formation of nitride semiconductor films, and can be used as a support substrate for the LED of the light emitting device 100, similar to the amorphous glass substrate or the resin substrate.

Although not shown in the figures, the substrate 110 may be provided with a base layer. The base layer can prevent impurities from the substrate 110 or impurities from the outside (e.g., moisture, sodium (Na), etc.) from diffusing. For example, a silicon nitride (SiNₓ) film or the like can be used as the base layer. Further, for example, a laminated film of a silicon oxide (SiOₓ) film and a silicon nitride (SiNₓ) film can also be used as the base layer.

The conductive alignment layer 120 can improve the crystallinity of the nitride semiconductor film such as gallium nitride (GaN) formed on the conductive alignment layer 120. Specifically, the conductive alignment layer 120 can perform control so as to align a c-axis of the nitride semiconductor film formed on the conductive alignment layer 120 in the film thickness direction. In other words, the conductive alignment layer 120 can control such that the first nitride semiconductor layer 130 has a c-axis orientation. Although a nitride semiconductor having a hexagonal close-packed structure grows in the c-axis direction to minimize surface energy, the crystal growth in the c-axis direction is promoted by forming the nitride semiconductor film on the conductive alignment layer 120. A conductive material having a hexagonal close-packed structure, a face-centered cubic structure, or a structure equivalent thereto can be used as the conductive alignment layer 120. Here, the structure equivalent to the hexagonal close-packed structure or the face-centered cubic structure includes a crystal structure in which the c-axis is not 90 degrees with respect to the a-axis and the b-axis. The conductive alignment layer 120 using the conductive material having the hexagonal close-packed structure or the structure equivalent thereto has an orientation in the (0001) direction, that is, the c-axis direction with respect to the substrate 110 (hereinafter, referred to as a (0001) orientation of the hexagonal close-packed structure.). Further, the conductive alignment layer 120 using the conductive material having the face-centered cubic structure or the structure equivalent thereto has an orientation in the (111) direction with respect to the substrate 110 (hereinafter, referred to as a (111) orientation of the face-centered cubic structure.). When the conductive alignment layer 120 has the (0001) orientation of the hexagonal close-packed structure or the (111) orientation of a face-centered cubic structure, the crystal growth of the nitride semiconductor film formed on the conductive alignment layer 120 is promoted. Therefore, the first nitride semiconductor layer 130 has a c-axis orientation with high crystallinity.

As described above, the crystallinity of the nitride semiconductor film on the conductive alignment layer 120 is affected by the surface condition of the conductive alignment layer 120. Therefore, it is preferable that the conductive alignment layer 120 has a smooth surface with little unevenness. For example, the arithmetic mean roughness (Ra) of the surface of the conductive alignment layer 120 is preferably less than 2.3 nm. Further, the root mean square roughness (Rq) of the surface of the alignment layer 120 is preferably less than 2.9 nm. When the surface roughness of the conductive alignment layer 120 is under the above conditions, the first nitride semiconductor layer 130 has the c-axis orientation with higher crystallinity. In addition, the thickness of the conductive alignment layer 120 is preferably greater than or equal to 50 nm.

The conductive alignment layer 120 has conductivity and can also function as an electrode for the LED. For example, titanium (Ti), titanium nitride (TiNₓ), titanium oxide (TiOₓ), graphene, zinc oxide (ZnO), magnesium diboride (MgB₂), aluminum (Al), silver (Ag), calcium (Ca), nickel (Ni), copper (Cu), strontium (Sr), rhodium (Rh), palladium (Pd), cerium (Ce), ytterbium (Yb), iridium (Ir), platinum (Pt), gold (Au), lead (Pb), actinium (Ac), thorium (Th), BiLaTiO, SrFeO, BiFeO, BaFeO, ZnFeO, PMnN-PZT, or the like can be used for the conductive alignment layer 120. In particular, it is preferable to use titanium, graphene, or zinc oxide for the conductive alignment layer 120.

The first nitride semiconductor layer 130 includes a first semiconductor layer of the LED. The first nitride semiconductor layer 130 on the conductive alignment layer 120 contains a nitride semiconductor and has the c-axis orientation with high crystallinity.

The second nitride semiconductor layer 140 includes a light emitting layer and a second semiconductor layer of the LED. Since the second nitride semiconductor layer 140 also includes a nitride semiconductor and is provided on the first nitride semiconductor layer 130 having the c-axis orientation with high crystallinity, the second nitride semiconductor layer 140 also has a c-axis orientation with high crystallinity. The light emitting layer is located between the first semiconductor layer and the second semiconductor layer. That is, the stack of the first nitride semiconductor layer 130 and the second nitride semiconductor layer 140 includes the first semiconductor layer, the light emitting layer, and the second semiconductor layer. One of the first semiconductor layer and the second semiconductor layer is an n-type nitride semiconductor layer, and the other of the first semiconductor layer and the second semiconductor layer is a p-type nitride semiconductor layer. For example, a gallium nitride film doped with silicon (Si) can be used as the n-type nitride semiconductor layer. For example, a laminated film in which indium gallium nitride (InGaN) films and gallium nitride films are alternately laminated can be used as the light emitting layer. For example, a gallium nitride film doped with magnesium (Mg) can be used as the p-type nitride semiconductor layer.

The electrode layer 150 functions as an electrode of the LED. For example, a transparent oxide such as indium tin oxide (ITO), indium zinc oxide (IZO), or zinc oxide (ZnO) can be used for the electrode layer 150. Further, a metal material such as indium (In), palladium (Pd), or gold (Au) can be used for the electrode layer 150. When the second semiconductor layer of the second nitride semiconductor layer 140 is a p-type nitride semiconductor layer, the electrode layer 150 is a p-type electrode, and for example, palladium or gold can be used for the electrode layer 150. Further, when the second semiconductor layer of the second nitride semiconductor layer 140 is an n-type nitride semiconductor layer, the electrode layer 150 is an n-type electrode, and for example, indium can be used for the electrode layer 150.

In the light emitting device 100, one of the conductive alignment layer 120 and the electrode layer 150 is a p-type electrode, and the other of the conductive alignment layer 120 and the electrode layer 150 is an n-type electrode. In order to extract light emitted from the light emitting layer of the second nitride semiconductor layer 140 to the outside, at least one of the p-type electrode and the n-type electrode may have translucency or semitranslucency. For example, a semi-transparent p-type electrode or n-type electrode can be formed using a thin metal.

The first rib 160 and the second rib 170 function as partition walls that partition each of the plurality of pixels 100-p. For example, an inorganic material such as silicon oxide or silicon nitride, or a laminate of these inorganic materials can be used for each of the first rib 160 and the second rib 170. Further, an organic material such as acrylic or polyimide can be used for each of the first rib 160 and the second rib 170.

Although not shown in the figures, a protective film may be provided to cover the LED, if necessary. A silicon nitride (SiNₓ) film can be used as the protective film. Further, for example, a laminated film of a silicon oxide (SiOₓ) film and a silicon nitride (SiNₓ) film can also be used as the protective film.

Each of the plurality of pixels 100-p includes the conductive alignment layer 120, the first nitride semiconductor layer 130, the second nitride semiconductor layer 140, and the electrode layer 150 for the LED. Here, one of the electrodes of the LED is the conductive alignment layer 120 and the other electrode of the LED is the electrode layer 150. The conductive alignment layer 120 and the electrode layer 150 are provided commonly in the plurality of pixels 100-p arranged in a matrix. Therefore, in the light emitting device 100 each of the plurality of pixels 100-p cannot be controlled. For convenience of explanation, the pixel 100-p may include the substrate 110.

### 2. Manufacturing Method of Light Emitting Device 100

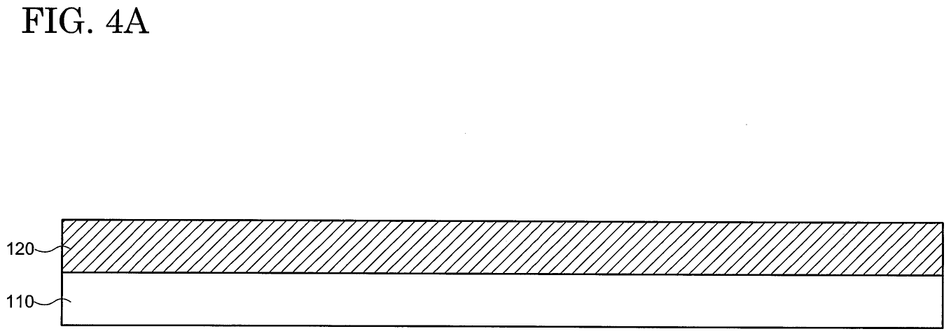

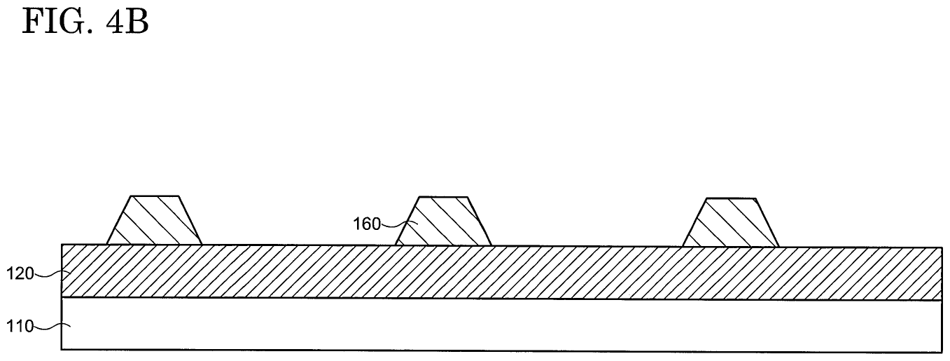

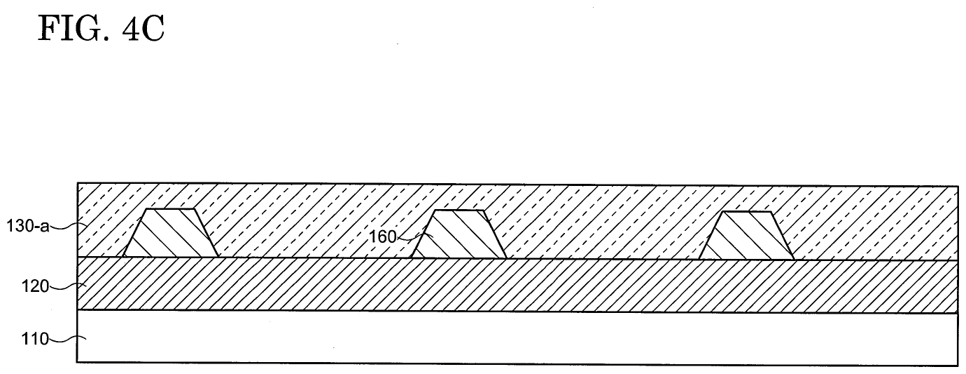

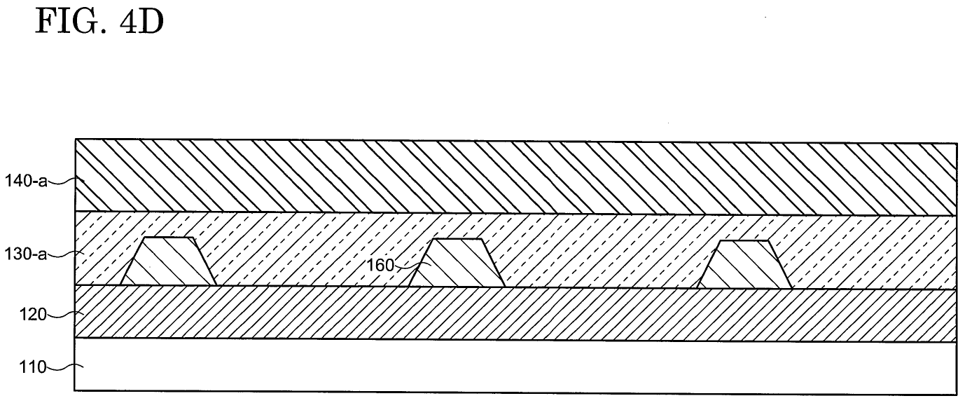

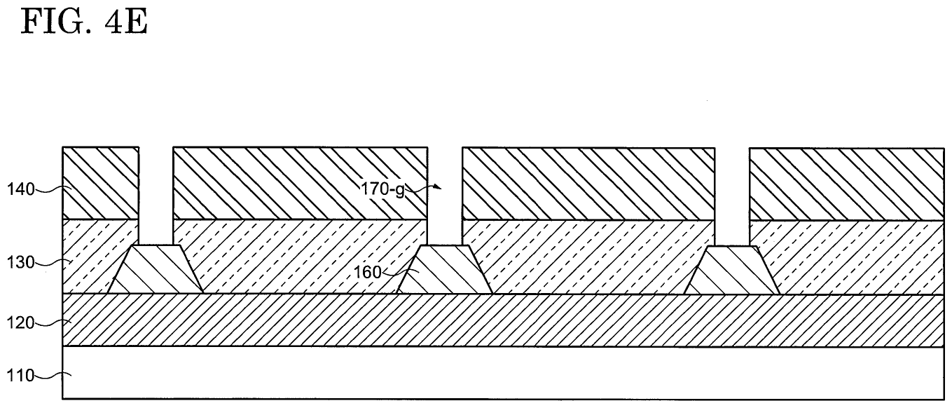

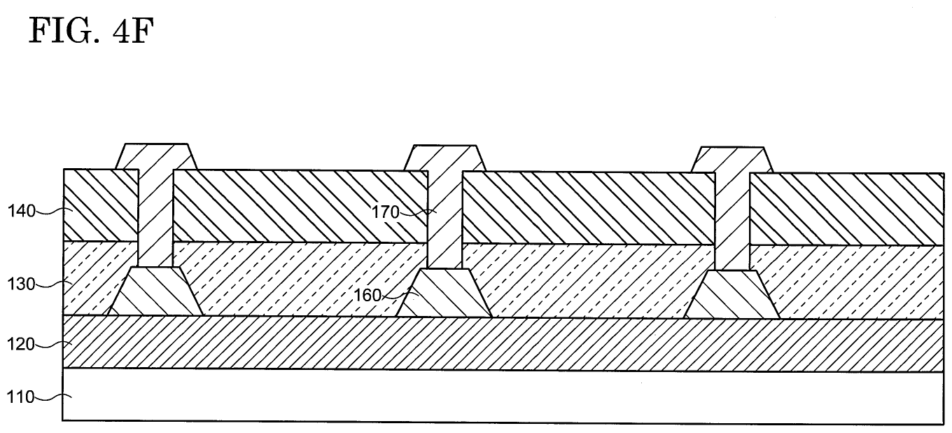

A method for manufacturing the light emitting device 100 according to an embodiment of the present invention is described with reference to FIG. 4A to FIG. 4F. FIG. 4A to FIG. 4F are schematic cross-sectional views showing a method of manufacturing the light emitting device 100 according to an embodiment of the present invention.

First, as shown in FIG. 4A, the conductive alignment layer 120 is formed on a substrate 110. The conductive alignment layer 120 can be formed using any method (apparatus) such as sputtering or CVD.

Next, as shown in FIG. 4B, the first rib 160 including the opening through which a part of the conductive alignment layer 120 is exposed is formed on the conductive alignment layer 120. The first rib 160 is formed by depositing an inorganic or organic material and then patterning the inorganic or organic material using photolithography.

Next, as shown in FIG. 4C, a first nitride semiconductor film 130-a is formed on the conductive alignment layer 120 and the first rib 160 so as to cover the opening of the first rib 160. The first nitride semiconductor film 130-acan be formed using sputtering. In the first nitride semiconductor film 130-a, a region in contact with the conductive alignment layer 120 has a c-axis orientation with high crystallinity.

Here, formation of a gallium nitride film is described as an example of forming a nitride semiconductor film using sputtering.

The substrate 110 on which a conductive alignment layer 120 is formed is placed to face a gallium nitride target in a vacuum chamber. It is preferable that the composition ratio of gallium nitride in the gallium nitride target is preferably greater than or equal to 0.7 and less than or equal to 2 of gallium to nitrogen. Further, nitrogen can also be supplied to the vacuum chamber as a gas other than the sputtering gas (such as argon or krypton). In that case, it is preferable that the composition ratio of gallium nitride in the gallium nitride target is more gallium than nitrogen. For example, nitrogen can be supplied using a nitrogen radical source. The sputtering power supply source may be either a DC power supply source, an RF power supply source, or a pulsed DC power supply source.

The substrate 110 in the vacuum chamber may be heated. For example, the substrate 110 can be heated at a temperature higher than or equal to 400 degrees and lower than 600 degrees. This substrate temperature can be applied even to an amorphous glass substrate with low heat resistance. Further, this substrate temperature is lower than the film formation temperature in MOCVD or HVPE.

After the vacuum chamber is sufficiently evacuated, the sputtering gas is supplied to the vacuum chamber. Further, a voltage is applied between the substrate 100 and the gallium nitride target at a predetermined pressure to generate plasma and the gallium nitride film is deposited.

Although the method for forming the gallium nitride film by sputtering is described above, the configuration or conditions of sputtering can be changed as appropriate. In addition, an n-type gallium nitride film (an n-type nitride semiconductor film) and a p-type gallium nitride film (a p-type nitride semiconductor film) can be formed by using a silicon-doped gallium nitride target and a magnesium-doped target, respectively, instead of the gallium nitride target.

Next, as shown in FIG. 4D, a second nitride semiconductor film 140-ais formed on the first nitride semiconductor film 130-a. The second nitride semiconductor film 140-a can be formed using sputtering. Since the second nitride semiconductor film 140-a is formed on the first nitride semiconductor film 130-a having the c-axis orientation with high crystallinity, the second nitride semiconductor film 140-a also has a c-axis orientation with high crystallinity, similar to the first nitride semiconductor film 130-a. Next, as shown in FIG. 4E, the first nitride semiconductor film 130-a and the second nitride semiconductor film 140-a are patterned using photolithography to form the second nitride semiconductor layer 140. Further, by patterning, a groove portion 170-g having a grid shape in which the first rib 160 is exposed is formed.

Next, as shown in FIG. 4F, the second rib 170 is formed on the first rib 160 to fill in the groove portion 170-g. The second rib 170 is formed by depositing an inorganic or organic material and then patterning the inorganic or organic material using photolithography. Further, by patterning, the second rib 170 is formed to cover at least the side surface of the second nitride semiconductor layer 140.

Finally, the electrode layer 150 is formed to cover the second nitride semiconductor layer 140 and the second rib 170, to manufacture the light emitting device 100 shown in FIGS. 1 to 3.

In the light emitting device 100, since the first nitride semiconductor layer 130 is provided on the conductive alignment layer 120, the crystallinity of the first nitride semiconductor layer 130 is improved. Further, since the second nitride semiconductor layer 140 is provided on the first nitride semiconductor layer 130 with improved crystallinity, the crystallinity of the second nitride semiconductor layer 140 including the light emitting layer is also improved. Therefore, the light emitting efficiency of the light emitting device 100 can be improved. Further, the conductive alignment layer 120 can be used for the electrode for the LED. Furthermore, by providing the conductive alignment layer 120 on the substrate 110, it is possible to manufacture the plurality of light emitting devices 100 using a large-area amorphous substrate as the substrate 110.

### Modification 1 of First Embodiment

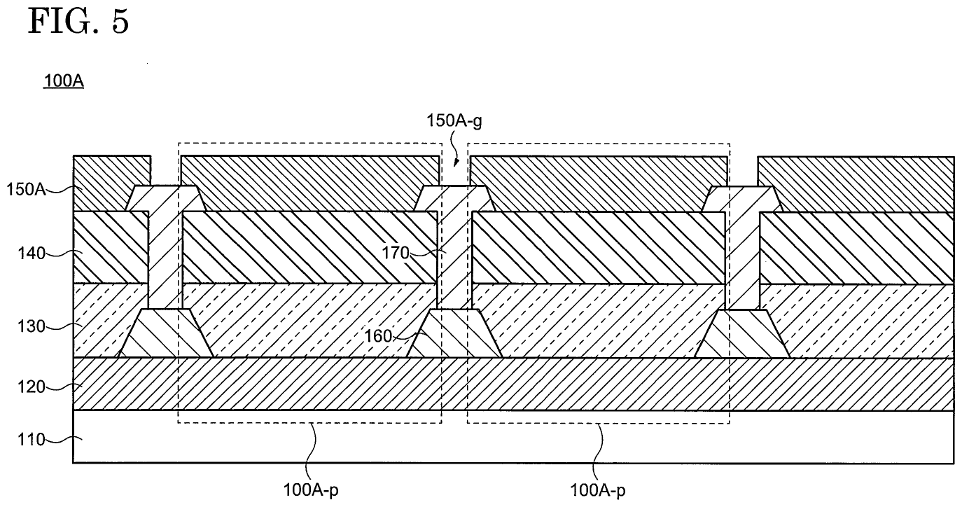

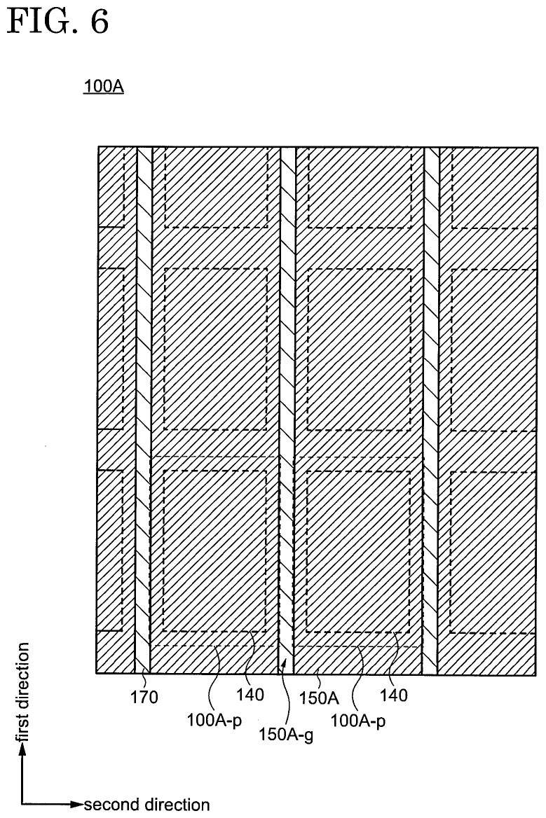

FIG. 5 and FIG. 6 are a schematic cross-sectional view and a schematic plan view showing a configuration of a light emitting device 100A according to an embodiment of the present invention. Specifically, FIG. 5 is a cross-sectional view of a pixel 100A-p. The light emitting device 100A is one modification of the light emitting device 100. Therefore, when the configuration of the light emitting device 100A is similar to the configuration of the light emitting device 100, the description thereof may be omitted.

As shown in FIG. 5, the light emitting device 100A includes the substrate 110, the conductive alignment layer 120, the first nitride semiconductor layer 130, the second nitride semiconductor layer 140, an electrode layer 150A, the first rib 160, and the second rib 170.

As shown in FIG. 6, the electrode layer 150A extends along the first direction of the pixels 100A-p arranged in a matrix, and is provided commonly in a plurality of pixels 100A-p arranged in the first direction. That is, the electrode layer 150A is provided commonly in the plurality of pixels 100A-p in one column. Further, the plurality of electrode layers 150A are separated from each other by a groove portion 150A-g in which the second rib 170 is exposed.

Each of the plurality of pixels 100A-p includes the conductive alignment layer 120, the first nitride semiconductor layer 130, the second nitride semiconductor layer 140, and the electrode layer 150A for the LED. Here, one of the electrodes of the LED is the conductive alignment layer 120, and the other electrode of the LED is the electrode layer 150A. The conductive alignment layer 120 is provided commonly in the plurality of pixels 100A-p arranged in a matrix. On the other hand, the electrode layer 150A is provided commonly in the plurality of pixels 100A-p arranged in the first direction. Therefore, in the light emitting device 100A, light emission can be controlled using the plurality of pixels 100A-p arranged in the first direction as one unit.

### Modification 2 of First Embodiment

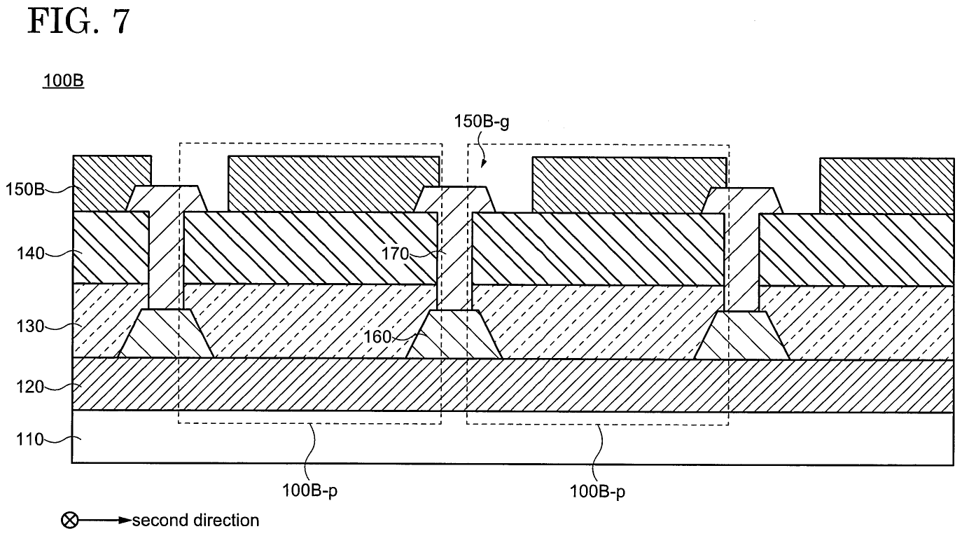

FIG. 7 is a schematic cross-sectional view showing a configuration of a light emitting device 100B according to an embodiment of the present invention. Specifically, FIG. 7 is a cross-sectional view of a pixel 100B-p. The light emitting device 100B is one modification of the light emitting device 100. Therefore, when the configuration of the light emitting device 100B is similar to the configuration of the light emitting device 100 or the light emitting device 100A, the description thereof may be omitted.

As shown in FIG. 7, the light emitting device 100B includes the substrate 110, the conductive alignment layer 120, the first nitride semiconductor layer 130, the second nitride semiconductor layer 140, an electrode layer 150B, the first rib 160, and the second rib 170.

Although not shown in the figures, the electrode layer 150B also extends along the first direction of the pixels 100B-p arranged in a matrix, and is provided commonly in a plurality of the pixels 100B-p arranged in the first direction, similar to the electrode layer 150A. That is, the electrode layer 150A is provided commonly in the plurality of pixels 100B-p in one column. Further, the plurality of electrode layers 150B are separated from each other by a groove portion 150B-g in which the second rib 170 is exposed.

Each of the plurality of pixels 100B-p includes the conductive alignment layer 120, the first nitride semiconductor layer 130, the second nitride semiconductor layer 140, and the electrode layer 150B for the LED. Here, one of the electrodes of the LED is the conductive alignment layer 120, and the other electrode of the LED is the electrode layer 150B. The conductive alignment layer 120 is provided commonly in the plurality of pixels 100B-p arranged in a matrix. On the other hand, the electrode layer 150B is provided commonly in the plurality of pixels 100B-p arranged in the first direction. Therefore, in the light emitting device 100B, light emission can be controlled using the plurality of pixels 100B-p arranged in the first direction as one unit.

Further, in the light emitting device 100B, not only the second rib 170 but also a part of the surface of the second nitride semiconductor layer 140 is exposed in the groove portion 150B-g. Therefore, even when the electrode layer 150B is formed using a non-light-transmitting material, light emitted from the light emitting layer of the second nitride semiconductor layer 140 can be extracted in the upper surface direction.

### Modification 3 of First Embodiment

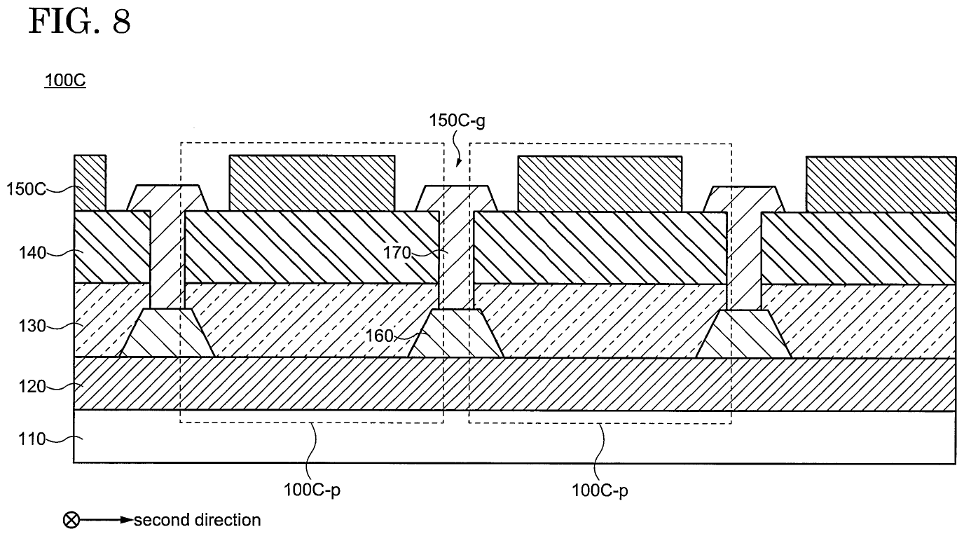

FIG. 8 is a schematic cross-sectional view showing a configuration of a light emitting device 100C according to an embodiment of the present invention. Specifically, FIG. 8 is a cross-sectional view of a pixel 100C-p. The light emitting device 100C is one modification of the light emitting device 100. Therefore, when the configuration of the light emitting device 100C is similar to the configurations of the light emitting devices 100 to 100B, the description thereof may be omitted.

As shown in FIG. 8, the light emitting device 100C includes the substrate 110, the conductive alignment layer 120, the first nitride semiconductor layer 130, the second nitride semiconductor layer 140, an electrode layer 150C, the first rib 160, and the second rib 170.

Although not shown in the figures, the electrode layer 150C also extends along the first direction of the pixels 100C-p arranged in a matrix, and is provided commonly in a plurality of the pixels 100C-p arranged in the first direction, similar to the electrode layer 150A. That is, the electrode layer 150A is provided commonly in the plurality of pixels 100C-p in one column. Further, the plurality of electrode layers 150C are separated from each other by a groove portion 150C-g in which the second rib 170 is exposed.

Each of the plurality of pixels 100C-p includes the conductive alignment layer 120, the first nitride semiconductor layer 130, the second nitride semiconductor layer 140, and the electrode layer 150C for the LED. Here, one of the electrodes of the LED is the conductive alignment layer 120, and the other electrode of the LED is the electrode layer 150C. The conductive alignment layer 120 is provided commonly in a plurality of pixels 100-p arranged in a matrix. On the other hand, the electrode layer 150C is provided commonly in the plurality of pixels 100C-p arranged in the first direction.

Therefore, in the light emitting device 100C, light emission can be controlled using the plurality of pixels 100C-p arranged in the first direction as one unit.

Further, in the light emitting device 100C, not only the second rib 170 but also a part of the surface of the second nitride semiconductor layer 140 is exposed in the groove portion 150C-g. Therefore, even when the electrode layer 150C is formed using a non-light-transmitting material, light emitted from the light emitting layer of the second nitride semiconductor layer 140 can be extracted in the upper surface direction. Furthermore, in the light emitting device 100C, the width of the electrode layer 150C is smaller than the opening width of the second rib 170 in the second direction orthogonal to the first direction. Therefore, the light emitting device 100C can extract more light toward the top surface than the light emitting device 100B.

### Second Embodiment

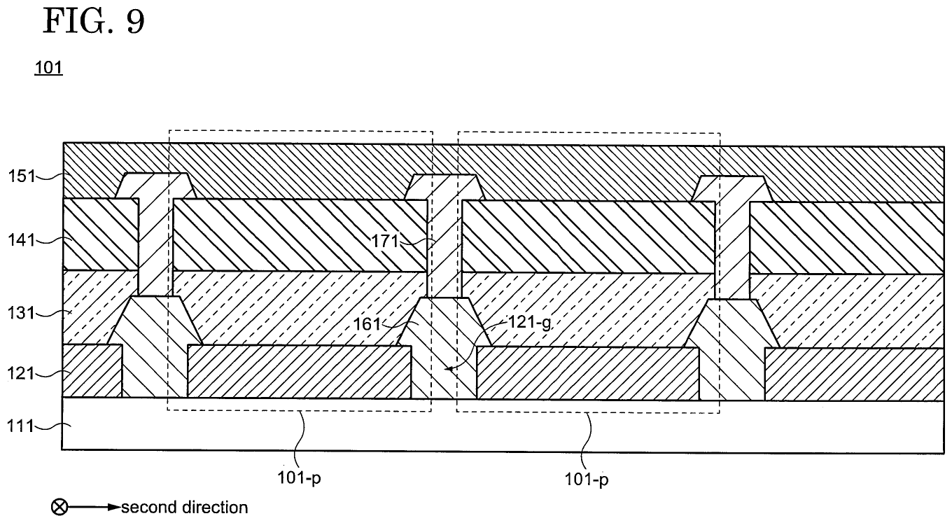

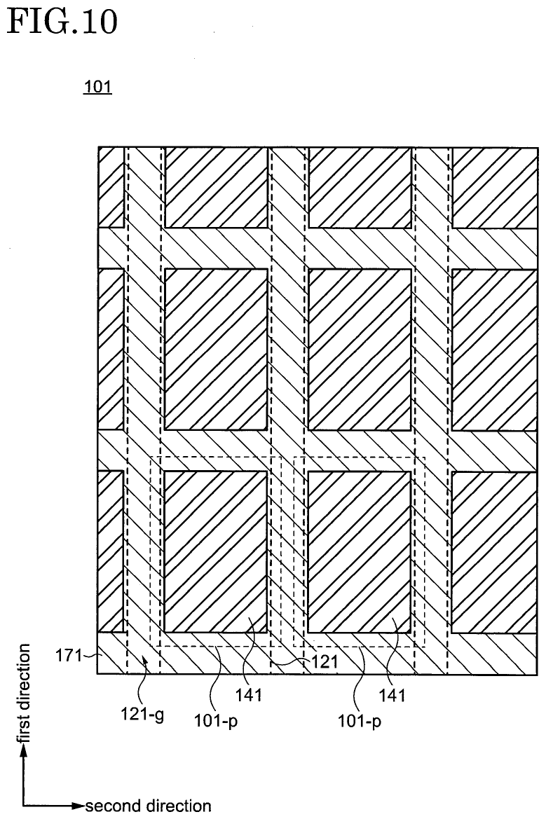

A light emitting device 101 according to an embodiment of the present invention is described with reference to FIG. 9 and FIG. 10. In addition, when the configuration of the light emitting device 101 is similar to the configuration of the light emitting device 100, the description thereof may be omitted.

FIG. 9 is a schematic cross-sectional view showing a configuration of the light emitting device 101 according to an embodiment of the present invention. Specifically, FIG. 9 is a cross-sectional view of a pixel 101-p. Further, FIG. 10 is a schematic plan view showing a configuration of the light emitting device 101 according to an embodiment of the present invention. In addition, in FIG. 10, a second nitride semiconductor layer 141 and an electrode layer 151 on a second rib 171 are omitted for convenience of explanation. Further, in FIG. 10, a conductive alignment layer 121 is shown by a broken line for convenience of explanation.

As shown in FIG. 9, the light emitting device 101 includes a substrate 111, a conductive alignment layer 121, a first nitride semiconductor layer 131, a second nitride semiconductor layer 141, an electrode layer 151, a first rib 161, and a second rib 171.

The conductive alignment layer 121 is provided on the substrate 111. Further, the conductive alignment layer 121 extends along the first direction and is provided commonly in a plurality of pixels 101-p arranged in the first direction. That is, the conductive alignment layer 121 is provided commonly in the plurality of pixels 101-p in one column. Further, the plurality of conductive alignment layers 121 are separated from each other by a groove portion 121-g in which the substrate 111 is exposed. In addition, the first rib 161 is filled in the groove portion 121-g.

The first nitride semiconductor layer 131 and the second nitride semiconductor layer 141 are provided over the conductive alignment layer 121 in this order. Further, each of the first nitride semiconductor layer 131 and the second nitride semiconductor layer 141 is provided in an island shape in each of the plurality of pixels 101-p arranged in a matrix.

The electrode layer 151 is provided on the second nitride semiconductor layer 141 and the second rib 171 so as to cover the second nitride semiconductor layer 141. Further, the electrode layer 151 is provided commonly in the plurality of pixels 101-p arranged in a matrix.

The first rib 161 is provided in a grid pattern on the substrate 111. Further, the second rib 171 is provided on the first rib 161 in a grid pattern.

Each of the plurality of pixels 101-p includes the conductive alignment layer 121, the first nitride semiconductor layer 131, the second nitride semiconductor layer 141, and the electrode layer 151 for an LED. Here, one of the electrodes of the LED is the conductive alignment layer 121, and the other electrode of the LED is the electrode layer 151. The conductive alignment layer 121 is provided commonly in the plurality of pixels 101-p arranged in the first direction. On the other hand, the electrode layer 151 is provided commonly in the plurality of pixels 101-p arranged in a matrix. Therefore, in the light emitting device 101, light emission can be controlled using the plurality of pixels 101-p arranged in the first direction as one unit. In addition, for convenience of explanation, the pixel 101-p may include the substrate 111.

In the light emitting device 101, since the first nitride semiconductor layer 131 is provided on the conductive alignment layer 121, the crystallinity of the first nitride semiconductor layer 131 is improved. Further, since the second nitride semiconductor layer 141 is provided on the first nitride semiconductor layer 131 with improved crystallinity, the crystallinity of the second nitride semiconductor layer 141 including the light emitting layer is also improved. Therefore, the light emitting efficiency of the light emitting device 101 can be improved. Further, the conductive alignment layer 121 can be used for the electrode for the LED. Furthermore, by providing the conductive alignment layer 121 on the substrate 111, it is possible to manufacture the plurality of light emitting devices 101 using a large-area amorphous substrate as the substrate 111.

### Modification 1 of Second Embodiment

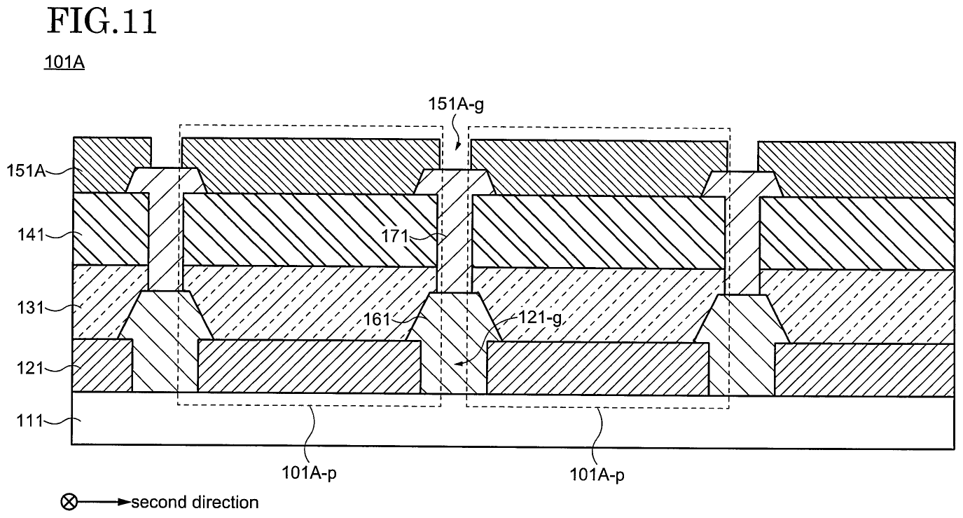

FIG. 11 is a schematic diagram showing a configuration of a light emitting device 101A according to an embodiment of the present invention. Specifically, FIG. 11 is a cross-sectional view of a pixel 101A-p. The light emitting device 101A is one modification of the light emitting device 101. Therefore, when the configuration of the light emitting device 101A is similar to the configuration of the light emitting device 101, the description thereof may be omitted.

As shown in FIG. 11, the light emitting device 101A includes the substrate 111, the conductive alignment layer 121, the first nitride semiconductor layer 131, the second nitride semiconductor layer 141, an electrode layer 151A, the first rib 161, and the second rib 171.

Although not shown in the figures, the electrode layer 151A extends along the first direction of the pixels 101A-p arranged in a matrix, and is provided commonly in a plurality of pixels 101A-p arranged in the first direction. That is, the electrode layer 151A is provided commonly in the plurality of pixels 101A-p in one column. Further, the plurality of electrode layers 151A are separated from each other by a groove portion 151A-g in which the second rib 171 is exposed.

Each of the plurality of pixels 101A-p includes the conductive alignment layer 121, the first nitride semiconductor layer 131, the second nitride semiconductor layer 141, and the electrode layer 151A for the LED. Here, one of the electrodes of the LED is the conductive alignment layer 121, and the other electrode of the LED is the electrode layer 151A. The conductive alignment layer 121 is provided commonly in the plurality of pixels 101A-p arranged in a matrix. On the other hand, the electrode layer 151A is provided commonly in the plurality of pixels 101A-p arranged in the first direction. Therefore, in the light emitting device 101A, light emission can be controlled using the plurality of pixels 101A-p arranged in the first direction as one unit.

### Modification 2 of Second Embodiment

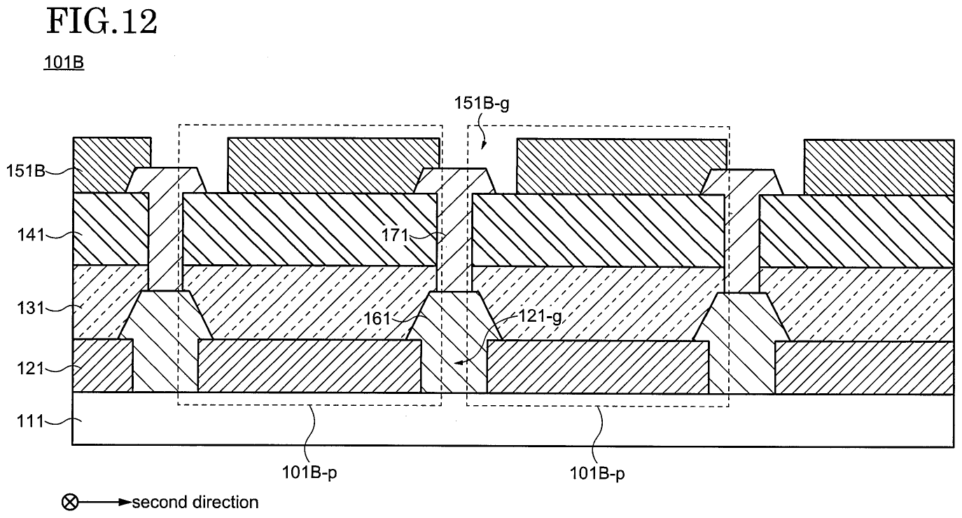

FIG. 12 is a schematic cross-sectional view showing a configuration of a light emitting device 101B according to an embodiment of the present invention. Specifically, FIG. 12 is a cross-sectional view of a pixel 101B-p. The light emitting device 101B is one modification of the light emitting device 101. Therefore, when the configuration of the light emitting device 101B is similar to the configuration of the light emitting device 101 or the light emitting device 101A, the description thereof may be omitted.

As is shown in FIG. 12, the light emitting device 101B includes the substrate 111, the conductive alignment layer 121, the first nitride semiconductor layer 131, the second nitride semiconductor layer 141, an electrode layer 151B, the first rib 161, and the second rib 171.

Although not shown in the figures, the electrode layer 151B also extends along the first direction of the pixels 101B-p arranged in a matrix, and is provided commonly in a plurality of pixels 101B arranged in the first direction, similar to the electrode layer 151A. That is, the electrode layer 151B is provided commonly in the plurality of pixels 101B-p in one column. Further, the plurality of electrode layers 151B are separated from each other by a groove portion 151B-g in which the second rib 171 is exposed.

Each of the plurality of pixels 101B-p includes the conductive alignment layer 121, the first nitride semiconductor layer 131, the second nitride semiconductor layer 141, and the electrode layer 151B for the LED. Here, one of the electrodes of the LED is the conductive alignment layer 121, and the other electrode of the LED is the electrode layer 151B. The conductive alignment layer 121 is provided commonly in the plurality of pixels 100B-p arranged in a matrix. On the other hand, the electrode layer 151B is provided commonly in the plurality of pixels 101B-p arranged in the first direction. Therefore, in the light emitting device 101B, light emission can be controlled using the plurality of pixels 101B-p arranged in the first direction as one unit.

Further, in the light emitting device 101B, not only the second rib 171 but also a part of the surface of the second nitride semiconductor layer 141 is exposed in the groove portion 151B-g. Therefore, even when the electrode layer 151B is formed using a non-light-transmitting material, light emitted from the light emitting layer of the second nitride semiconductor layer 141 can be extracted in the upper surface direction.

### Modification 3 of Second Embodiment

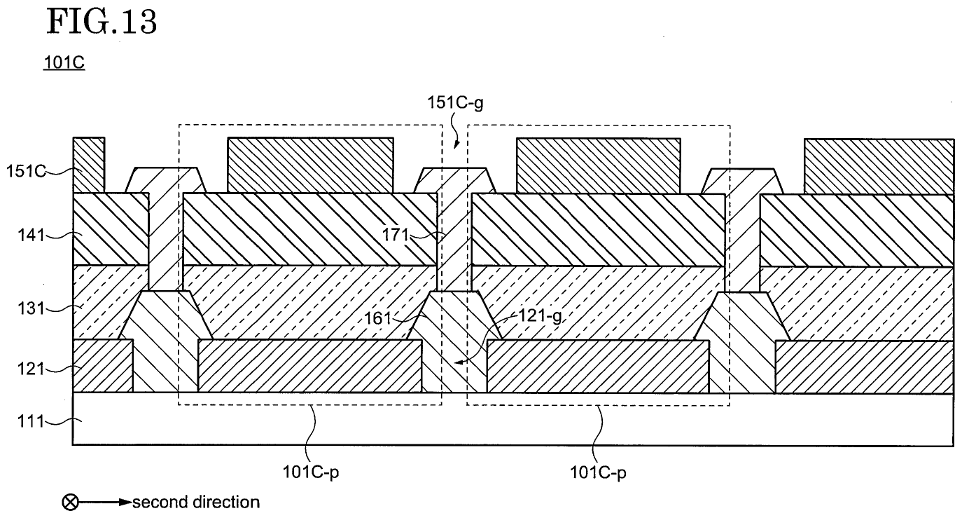

FIG. 13 is a schematic cross-sectional view showing a configuration of a light emitting device 101C according to an embodiment of the present invention. Specifically, FIG. 13 is a cross-sectional view of a pixel 101C-p. The light emitting device 101C is one modification of the light emitting device 101. Therefore, when the configuration of the light emitting device 101C is similar to the configurations of the light emitting devices 101 to 101B, the description thereof may be omitted.

As shown in FIG. 13, the light emitting device 101C includes the substrate 111, the conductive alignment layer 121, the first nitride semiconductor layer 131, the second nitride semiconductor layer 141, the electrode layer 151C, the first rib 161, and the second rib 171.

Although not shown in the figures, the electrode layer 151C also extends along the first direction of the pixels 101C-p arranged in a matrix, and is provided commonly in a plurality of pixels 101C-p arranged in the first direction, similar to the electrode layer 151A. That is, the electrode layer 151C is provided commonly in the plurality of pixels 101C-p in one column. Further, the plurality of electrode layers 151C are separated from each other by a groove portion 151C-g in which the second rib 171 is exposed.

Each of the plurality of pixels 101C-p includes the conductive alignment layer 121, the first nitride semiconductor layer 131, the second nitride semiconductor layer 141, and the electrode layer 151C for an LED. Here, one of the electrodes of the LED is the conductive alignment layer 121, and the other electrode of the LED is the electrode layer 151C. The conductive alignment layer 121 and the electrode layer 151C are provided commonly in the plurality of pixels 101C-p arranged in the first direction. Therefore, in the light emitting device 101C, light emission can be controlled using the plurality of pixels 101C-p arranged in the first direction as one unit.

Further, in the light emitting device 101C, not only the second rib 171 but also a part of the surface of the second nitride semiconductor layer 141 is exposed in the groove portion 150C-g. Therefore, even when the electrode layer 151C is formed using a non-light-transmitting material, light emitted from the light emitting layer of the second nitride semiconductor layer 141 can be extracted in the upper surface direction. Furthermore, in the light emitting device 101C, the width of the electrode layer 151C is smaller than the opening width of the second rib 171 in the second direction orthogonal to the first direction. Therefore, the light emitting device 101C can extract more light toward the top surface than the light emitting device 101B.

### Modification 4 of Second Embodiment

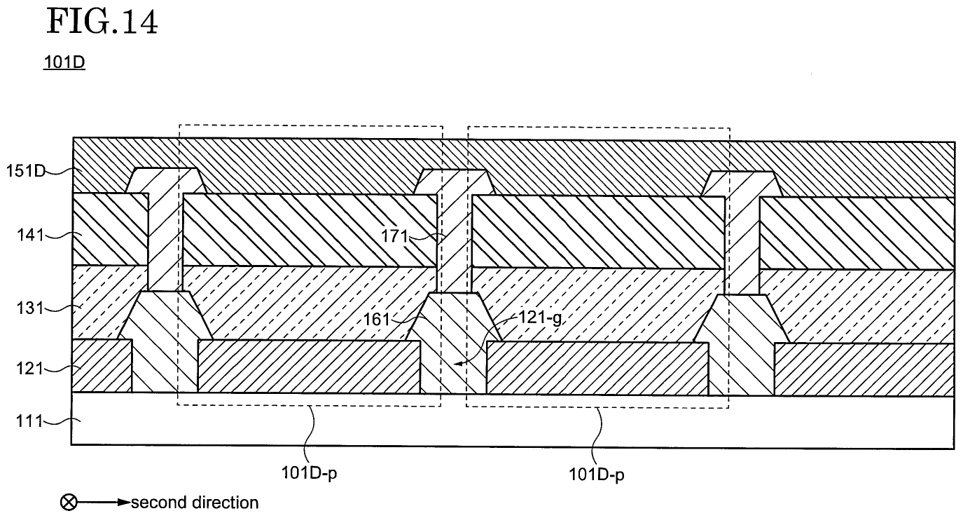

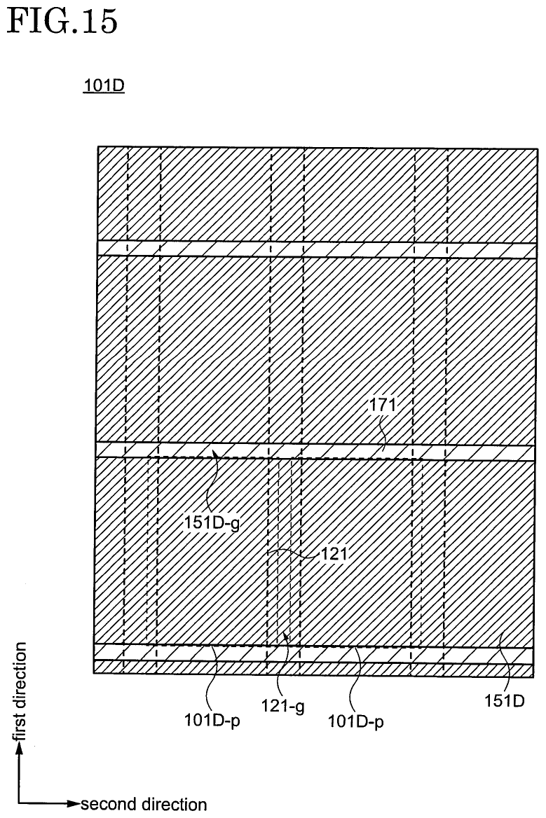

FIG. 14 and FIG. 15 are a schematic cross-sectional view and a schematic plan view showing a configuration of a light emitting device 101D according to an embodiment of the present invention. Specifically, FIG. 14 is a cross-sectional view of a pixel 101D-p. Further, in FIG. 15, the conductive alignment layer 121 is shown by a broken line for convenience of explanation. The light emitting device 101D is one modification of the light emitting device 101. Therefore, when the configuration of the light emitting device 101D is similar to the configurations of the light emitting devices 101 to 101C, the description thereof may be omitted.

As shown in FIG. 14, the light emitting device 101D includes the substrate 111, the conductive alignment layer 121, the first nitride semiconductor layer 131, the second nitride semiconductor layer 141, an electrode layer 151D, the first rib 161, and the second rib 170.

As shown in FIG. 15, the electrode layer 151D extends along the second direction orthogonal to the first direction of the pixels 101D-p arranged in a matrix, and is provided commonly in a plurality of pixels 101D-p arranged in the second direction. That is, the electrode layer 151D is provided commonly in the plurality of pixels 101D-p in one row. Further, the plurality of electrode layers 151D are separated from each other by a groove portion 150D-g in which the second rib 171 is exposed.

Each of the plurality of pixels 101D-p includes the conductive alignment layer 121, the first nitride semiconductor layer 131, the second nitride semiconductor layer 141, and the electrode layer 151D for an LED. Here, one of the electrodes of the LED is the conductive alignment layer 121, and the other electrode of the LED is the electrode layer 151D. The conductive alignment layer 121 is provided commonly in the plurality of pixels 101D-p arranged in the first direction. On the other hand, the electrode layer 151D is provided commonly in the plurality of pixels 101D-p arranged in the second direction. Therefore, in the light emitting device 101D, light emission of the pixel 101D-p at the intersection of the conductive alignment layer 121 and the electrode layer 151D can be controlled. That is, in the light emitting device 101D, the light emission of the pixel 101D-p can be controlled by passive driving .

### Modification 5 of Second Embodiment

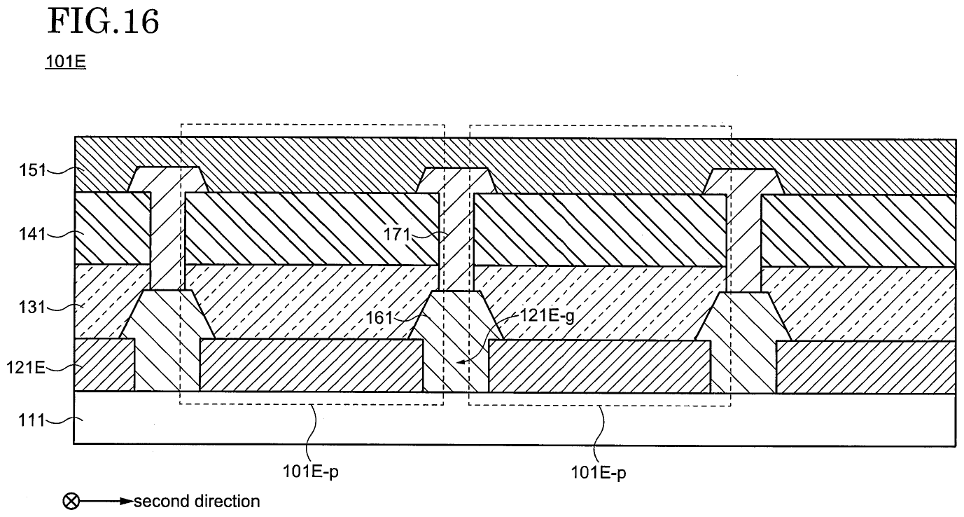

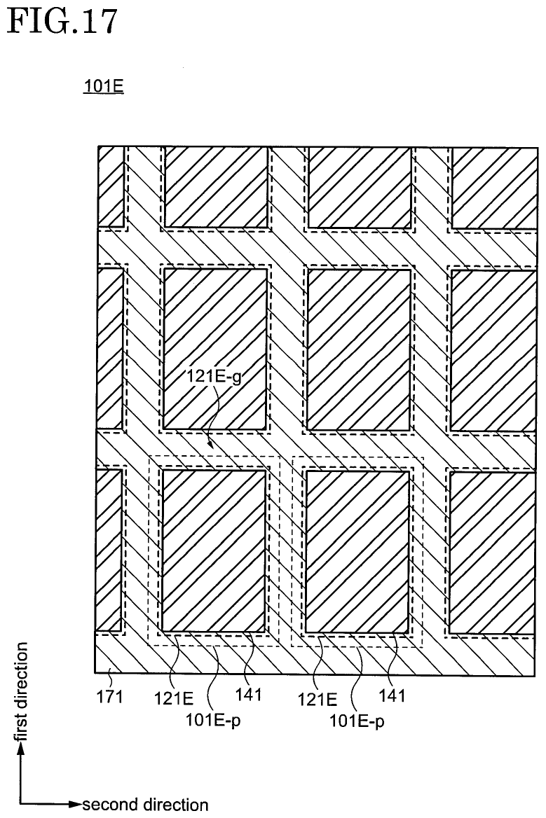

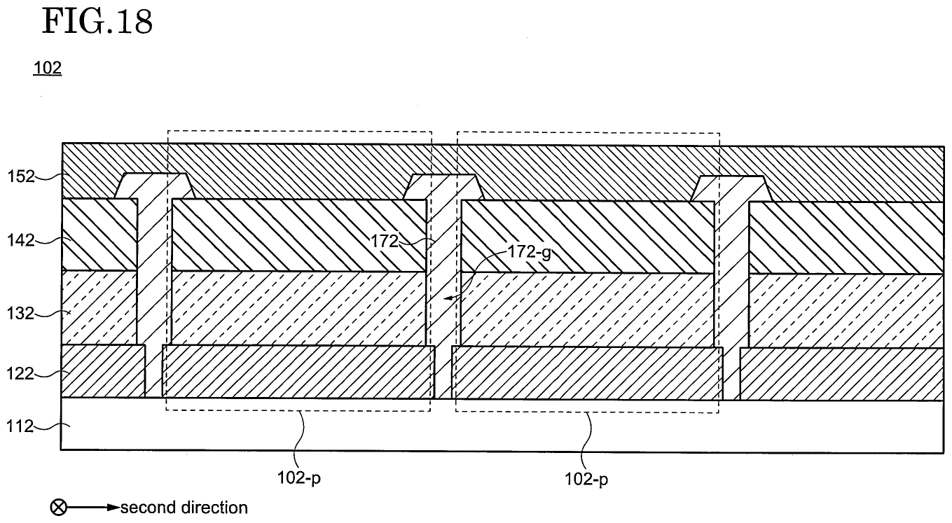

FIG. 16 and FIG. 17 are a schematic cross-sectional view and a schematic plan view showing a configuration of a light emitting device 101E according to an embodiment of the present invention. Specifically, FIG. 16 is a cross-sectional view of the pixel 101Ep. Further, in FIG. 17, the second nitride semiconductor layer 141 and the electrode layer 151 on the second rib 171 are omitted for convenience of explanation. Furthermore, in FIG. 17, a conductive alignment layer 121E, which is described later, is shown by a broken line for convenience of explanation. The light emitting device 101E is one modification of the light emitting device 101. Therefore, when the configuration of the light emitting device 101E is similar to the configurations of the light emitting devices 101 to 101D, the description thereof may be omitted.

As shown in FIG. 16, the light emitting device 101E includes the substrate 111, a conductive alignment layer 121E, the first nitride semiconductor layer 131, the second nitride semiconductor layer 141, the electrode layer 151, the first rib 161, and the second rib 171.

As shown in FIG. 17, the conductive alignment layer 121E is provided in an island shape in each of the pixels 101E-p arranged in a matrix. Further, the plurality of conductive alignment layers 121E are separated from each other by a groove portion 121E-g provided in a grid pattern.

Each of the plurality of pixels 101E-p includes the conductive alignment layer 121E, the first nitride semiconductor layer 131, the second nitride semiconductor layer 141, and the electrode layer 151 for an LED. Here, one of the electrodes of the LED is the conductive alignment layer 121E, and the other electrode of the LED is the electrode layer 151. The conductive alignment layer 121E is provided in an island shape in each of the plurality of pixels 101E-p arranged in a matrix. On the other hand, the electrode layer 151 is provided commonly in the plurality of pixels 101E-p arranged in a matrix. In the light emitting device 101E, the substrate 111 is provided with, for example, a transistor that controls the LED. Further, each of the plurality of conductive alignment layers 121E is electrically connected to the transistor. Therefore, in the light emitting device 101E, light emission of each of the plurality of pixels 101E-p arranged in a matrix can be controlled. That is, in the light emitting device 101E, the light emission of the pixels 101E-p can be controlled by active driving.

### Third Embodiment

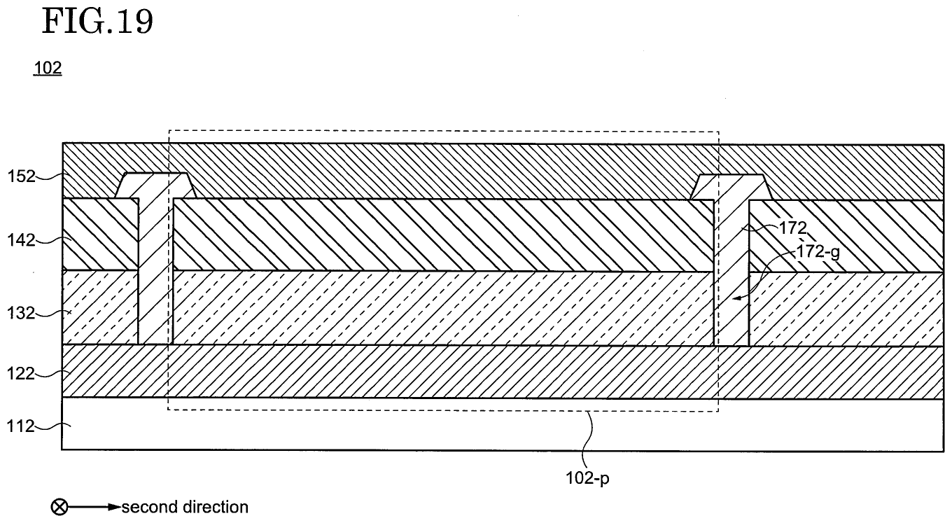

A light emitting device 102 according to an embodiment of the present invention is described with reference to FIG. 18 and FIG. 19. In addition, when a configuration of the light emitting device 102 is similar to the configuration of the light emitting device 100 or the light emitting device 101, the description thereof may be omitted.

FIGS. 18 and 19 are schematic cross-sectional views showing a configuration of the light emitting device 102 according to an embodiment of the present invention. Specifically, FIG. 18 and FIG. 19 are cross-sectional views of a pixel 102-p.

As shown in FIG. 18, the light emitting device 102 includes a substrate 112, a conductive alignment layer 122, a first nitride semiconductor layer 132, a second nitride semiconductor layer 142, an electrode layer 152, and a rib 172.

The conductive alignment layer 122 is provided on the substrate 112. Further, the conductive alignment layer 122 extends along the first direction and is provided commonly in a plurality of pixels 102-p arranged in the first direction. That is, the conductive alignment layer 122 is provided commonly in the plurality of pixels 102-p in one column. Further, the plurality of conductive alignment layers 122 are separated from each other by a groove portion 172-g in which the substrate 112 is exposed. In addition, the groove portion 172-g is filled with the rib 172.

The first nitride semiconductor layer 132 and the second nitride semiconductor layer 142 are provided over the conductive alignment layer 122 in this order. Further, each of the first nitride semiconductor layer 132 and the second nitride semiconductor layer 142 is provided in an island shape in each of the plurality of pixels 102-p arranged in a matrix.

The electrode layer 152 is provided on the second nitride semiconductor layer 142 and the rib 172 so as to cover the second nitride semiconductor layer 142. Further, the electrode layer 152 is provided commonly in the plurality of pixels 102-p arranged in a matrix.

The rib 172 is provided on the substrate 112 in a grid pattern. That is, the rib 172 is provided so as to fill the groove portion 172-g provided in a grid pattern. As shown in FIG. 18 and FIG. 19, the depth of the groove portion 172-g varies depending on the extending direction. As shown in FIG. 18, in the second direction of the pixel 102-p, the groove portion 172-g is provided so that the surface of the substrate 112 is exposed. On the other hand, as shown in FIG. 19, in the first direction orthogonal to the second direction, the groove portion 172-g is provided so that the surface of the conductive alignment layer 122 extending in the first direction is exposed.

Each of the plurality of pixels 102-p includes the conductive alignment layer 122, the first nitride semiconductor layer 132, the second nitride semiconductor layer 142, and the electrode layer 152 for an LED. Here, one of the electrodes of the LED is the conductive alignment layer 122 and the other electrode of the LED is the electrode layer 152. The conductive alignment layer 122 is provided commonly in the plurality of pixels 102-p arranged in the first direction. On the other hand, the electrode layer 152 is provided commonly in the plurality of pixels 102-p arranged in a matrix. Therefore, in the light emitting device 102, light emission can be controlled using the plurality of pixels 102-p arranged in the first direction as one unit. In addition, the pixel 102-p may include the substrate 112 for convenience of explanation.

In the light emitting device 102, since the first nitride semiconductor layer 132 is provided on the conductive alignment layer 122, the crystallinity of the first nitride semiconductor layer 132 is improved. Further, since the second nitride semiconductor layer 142 is provided on the first nitride semiconductor layer 132 with improved crystallinity, the crystallinity of the second nitride semiconductor layer 142 including the light emitting layer is also improved.

Therefore, the light emitting efficiency of the light emitting device 102 can be improved. Further, the conductive alignment layer 122 can be used as the electrode for an LED. Furthermore, by providing the conductive alignment layer 122 on the substrate 112, it is possible to manufacture a plurality of light emitting devices 102 using a large-area amorphous substrate as the substrate 112.

### Modification 1 of Third Embodiment

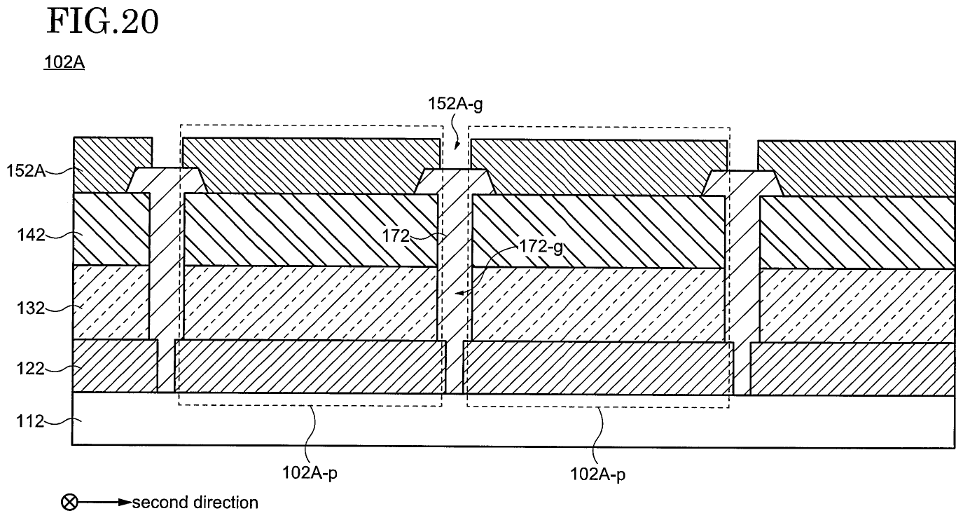

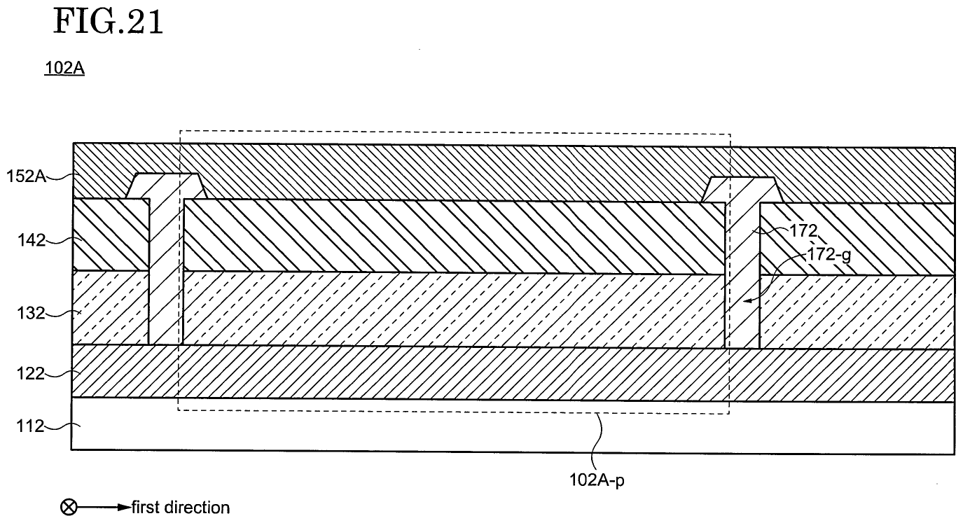

FIG. 20 and FIG. 21 are schematic diagrams showing a configuration of a light emitting device 102A according to an embodiment of the present invention. Specifically, FIG. 20 and FIG. 21 are cross-sectional views of a pixel 102A-p. The light emitting device 102A is one modification of the light emitting device 102. Therefore, when the configuration of the light emitting device 102A is similar to the configuration of the light emitting device 102, the description thereof may be omitted.

As shown in FIG. 20, the light emitting device 102A includes the substrate 112, the conductive alignment layer 122, the first nitride semiconductor layer 132, the second nitride semiconductor layer 142, an electrode layer 152A, and the rib 172.

As shown in FIG. 20 and FIG. 21, the electrode layer 152A extends along the first direction of the pixels 102A-p arranged in a matrix, and is provided commonly in a plurality of pixels 102A-p arranged in the first direction. That is, the electrode layer 152A is provided commonly in the plurality of pixels 102A-p in one column. Further, the plurality of electrode layers 152A are separated from each other by a groove portion 152A-g in which the surfaces of the rib 172 are exposed.

Each of the plurality of pixels 102A-p includes the conductive alignment layer 122, the first nitride semiconductor layer 132, the second nitride semiconductor layer 142, and the electrode layer 152A for an LED. Here, one of the electrodes of the LED is the conductive alignment layer 122, and the other electrode of the LED is the electrode layer 152A. The conductive alignment layer 122 and the electrode layer 152A are provided commonly in the plurality of pixels 102A-p arranged in the first direction. Therefore, in the light emitting device 102A, light emission can be controlled using the plurality of pixels 102A-p arranged in the first direction as one unit.

### Modification 2 of Third Embodiment

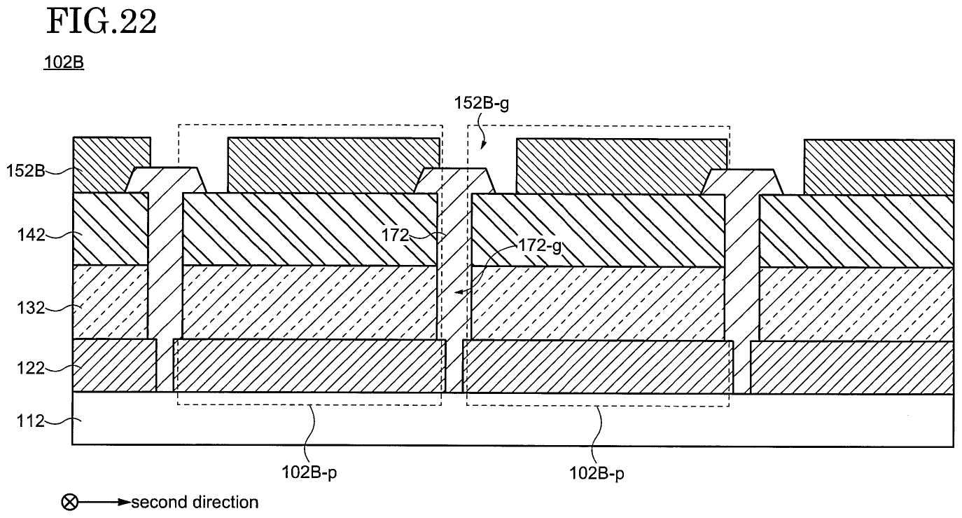

FIG. 22 is a schematic cross-sectional view showing a configuration of a light emitting device 102B according to an embodiment of the present invention. Specifically, FIG. 22 is a cross-sectional view of a pixel 102B-p. The light emitting device 102B is one modification of the light emitting device 102. Therefore, when the configuration of the light emitting device 102B is similar to the configuration of the light emitting device 102 or the light emitting device 102A, the description thereof may be omitted.

As shown in FIG. 22, the light emitting device 102B includes the substrate 112, the conductive alignment layer 122, the first nitride semiconductor layer 132, the second nitride semiconductor layer 142, an electrode layer 152B, and the rib 172.

Although not shown in the figures, the electrode layer 152B also extends along the first direction of the pixels 102B-p arranged in a matrix, and is provided commonly in a plurality of pixels 102B-p arranged in the first direction, similar to the electrode layer 152A. That is, the electrode layer 152B is provided commonly in the plurality of pixels 102B-p in one column. Further, the plurality of electrode layers 152B are separated from each other by a groove portion 152B-g in which the rib 172 is exposed.

Each of the plurality of pixels 102B-p includes the conductive alignment layer 122, the first nitride semiconductor layer 132, the second nitride semiconductor layer 142, and the electrode layer 152B for an LED. Here, one of the electrodes of the LED is the conductive alignment layer 122, and the other electrode of the LED is the electrode layer 152B. The conductive alignment layer 122 and the electrode layer 152B are provided commonly in the plurality of pixels 102B-p arranged in the first direction. Therefore, in the light emitting device 102B, light emission can be controlled using the plurality of pixels 102B-p arranged in the first direction as one unit.

Further, in the light emitting device 102B, not only the rib 172 but also a part of the surface of the second nitride semiconductor layer 142 is exposed in the groove portion 152B-g. Therefore, even when the electrode layer 152B is formed using a non-light-transmitting material, light emitted from the second nitride semiconductor layer 142 can be extracted in the upper surface direction.

### Modification 3 of Third Embodiment

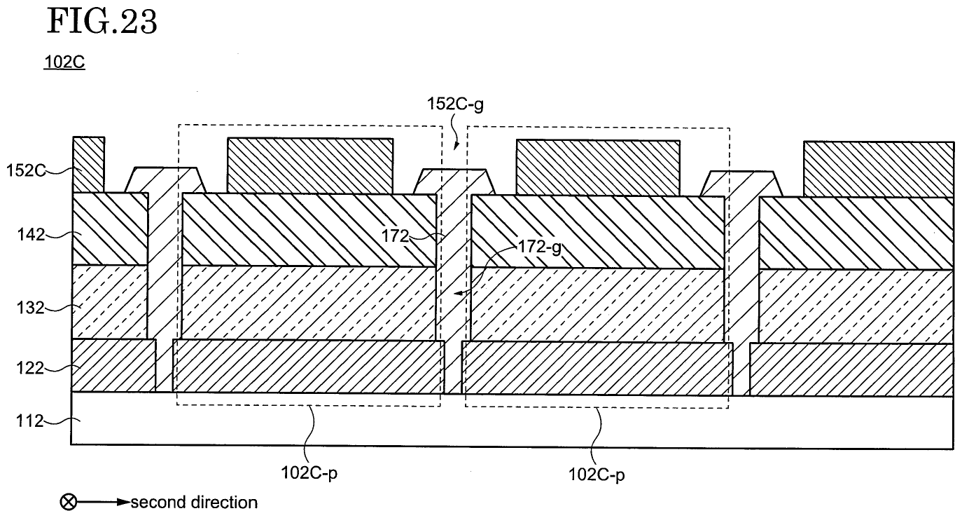

FIG. 23 is a schematic cross-sectional view showing a configuration of a light emitting device 102C according to an embodiment of the present invention. Specifically, FIG. 23 is a cross-sectional view of a pixel 102C-p. The light emitting device 102C is one modification of the light emitting device 102. Therefore, when the configuration of the light emitting device 102C is similar to the configurations of the light emitting devices 102 to 102B, the description thereof may be omitted.

As shown in FIG. 23, the light emitting device 102C includes the substrate 112, the conductive alignment layer 122, the first nitride semiconductor layer 132, the second nitride semiconductor layer 142, an electrode layer 152C, and the rib 172.

Although not shown in the figures, the electrode layer 152C also extends along the first direction of the pixels 102C-p arranged in a matrix, and is provided commonly in a plurality of pixels 102C-p arranged in the first direction, similar to the electrode layer 152A. That is, the electrode layer 152C is provided commonly in the plurality of pixels 102C-p in one column. Further, the plurality of electrode layers 152C are separated from each other by a groove portion 152C-g in which the rib 172 is exposed.

Each of the plurality of pixels 102C-p includes the conductive alignment layer 122, the first nitride semiconductor layer 132, the second nitride semiconductor layer 142, and the electrode layer 152C for an LED. Here, one of the electrodes of the LED is the conductive alignment layer 122, and the other electrode of the LED is the electrode layer 152C. The conductive alignment layer 122 and the electrode layer 152C are provided commonly in the plurality of pixels 102C-p arranged in the first direction. Therefore, in the light emitting device 102C, light emission can be controlled using the plurality of pixels 102C-p arranged in the first direction as one unit.

Further, in the light emitting device 102C, not only the rib 172 but also a part of the surface of the second nitride semiconductor layer 142 is exposed in the groove portion 152C-g. Therefore, even when the electrode layer 152C is formed using a non-light-transmitting material, light emitted from the light emitting layer of the second nitride semiconductor layer 142 can be extracted in the upper surface direction. Furthermore, in the light emitting device 101C, the width of the electrode layer 152C is smaller than the opening width of the rib 172 in the second direction orthogonal to the first direction. Therefore, the light emitting device 102C can extract more light toward the top surface than the light emitting device 102B.

### Fourth Embodiment

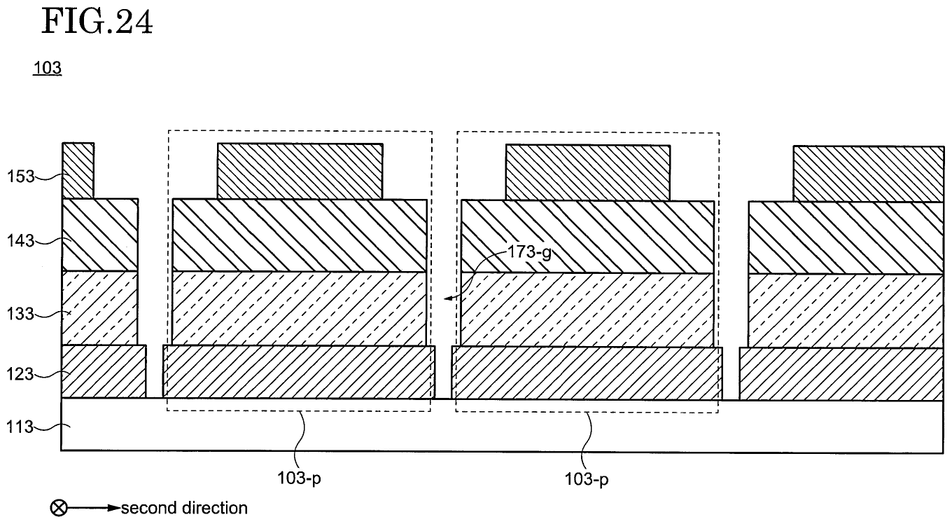

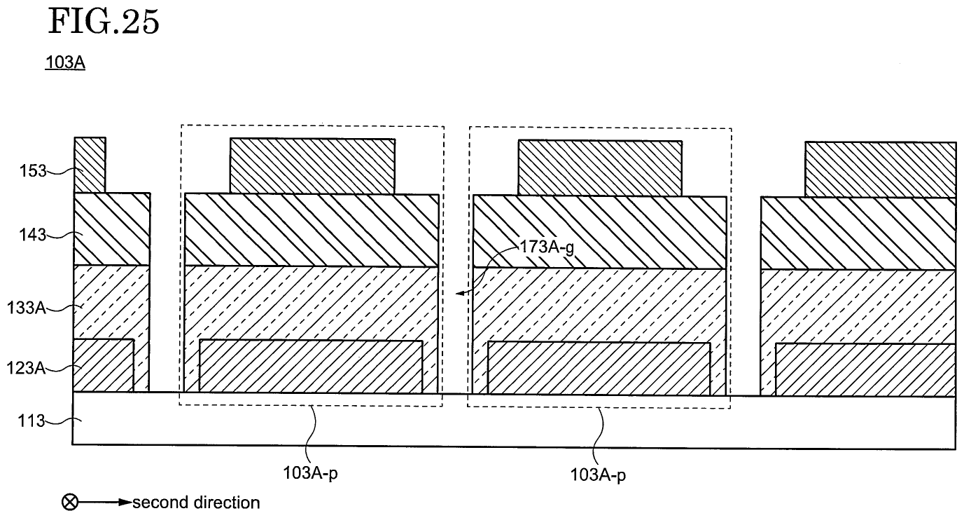

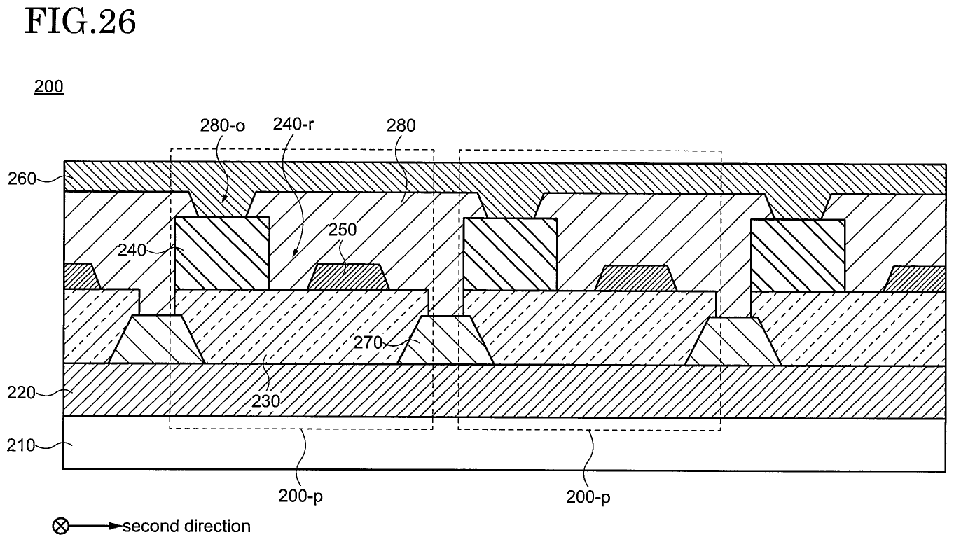

A light emitting device 103 according to an embodiment of the present invention is described with reference to FIG. 24. In addition, when a configuration of the light emitting device 103 is similar to the configurations of the light emitting devices 100 to 102, the description thereof may be omitted.

FIG. 24 is a schematic cross-sectional view showing a configuration of the light emitting device 103 according to an embodiment of the present invention. Specifically, FIG. 24 is a cross-sectional view of the pixel 103-p.

As shown in FIG. 24, the light emitting device 103 includes a substrate 113, a conductive alignment layer 123, a first nitride semiconductor layer 133, a second nitride semiconductor layer 143, and an electrode layer 153.

The conductive alignment layer 123 is provided on the substrate 113. Further, the conductive alignment layer 123 extends along the first direction and is provided commonly in a plurality of pixels 103-p arranged in the first direction. That is, the conductive alignment layer 123 is provided commonly in the plurality of pixels 103-p in one column. Further, the plurality of conductive alignment layers 123 are separated from each other by a groove portion 173-g in which the substrate 113 is exposed.

The first nitride semiconductor layer 133 and the second nitride semiconductor layer 143 are provided over the conductive alignment layer 123 in this order. Further, each of the first nitride semiconductor layer 133 and the second nitride semiconductor layer 143 is provided in an island shape in each of the plurality of pixels 103-p arranged in a matrix .

The electrode layer 153 is provided on the second nitride semiconductor layer 143. Further, the electrode layer 153 is provided in an island shape in each of the plurality of pixels 103-p arranged in a matrix. In addition, the position of the electrode layer 153 on the second nitride semiconductor layer 143 is not particularly limited thereto. Further, the size of the electrode layer 153 is not particularly limited thereto.

Each of the plurality of pixels 103-p includes the conductive alignment layer 123, the first nitride semiconductor layer 133, the second nitride semiconductor layer 143, and the electrode layer 153 for an LED. Here, one of the electrodes of the LED is the conductive alignment layer 123, and the other electrode of the LED is the electrode layer 153. The conductive alignment layer 123 is provided commonly in the plurality of pixels 103-p arranged in the first direction. On the other hand, the electrode layer 153 is provided in each of the plurality of pixels 103-p arranged in a matrix. In the light emitting device 103, a substrate on which a metal layer is formed, which is different from the substrate 113, is bonded to the substrate 113, and the plurality of electrode layers 153 are electrically connected to the metal layer. Therefore, in the light emitting device 103, light emission can be controlled using the plurality of pixels 103-p arranged in the first direction as one unit. In addition, the pixel 103-p may include the substrate 113 for convenience of explanation.

In the light emitting device 103, since the first nitride semiconductor layer 133 is provided on the conductive alignment layer 123, the crystallinity of the first nitride semiconductor layer 133 is improved. Further, since the second nitride semiconductor layer 143 is provided on the first nitride semiconductor layer 133 with improved crystallinity, the crystallinity of the second nitride semiconductor layer 143 including the light emitting layer is also improved. Therefore, the light emitting efficiency of the light emitting device 103 can be improved. Further, the conductive alignment layer 123 can be used as an electrode of the LED. Furthermore, by providing the conductive alignment layer 123 on the substrate 113, it is possible to manufacture the plurality of light emitting devices 103 using a large-area amorphous substrate as the substrate 113.

### Modification 1 of Fourth Embodiment

FIG. 25 is a schematic diagram showing a configuration of a light emitting device 103A according to an embodiment of the present invention. Specifically, FIG. 25 is a cross-sectional view of a pixel 103A-p. The light emitting device 103A is one modification of the light emitting device 103. Therefore, when the configuration of the light emitting device 103A is similar to the configuration of the light emitting device 103, the description thereof may be omitted.

As shown in FIG. 25, the light emitting device 103A includes the substrate 113, a conductive alignment layer 123A, a first nitride semiconductor layer 133A, the second nitride semiconductor layer 143, and the electrode layer 153.

The conductive alignment layer 123A also extends along the first direction of the pixels 103A-p arranged in a matrix, and is provided commonly in a plurality of pixels 103A-p arranged in the first direction, similar to the conductive alignment layer 123. That is, the conductive alignment layer 123A is provided commonly in the plurality of pixels 103A-p in one column.

The first nitride semiconductor layer 133A and the second nitride semiconductor layer 143 are provided in this order over the conductive alignment layer 123A. Further, each of the first nitride semiconductor layer 133 and the second nitride semiconductor layer 143 is provided in an island shape in each of the plurality of pixels 103A-p arranged in a matrix. The stacks of the first nitride semiconductor layer 133A and the second nitride semiconductor layer 143 are separated from each other by a groove portion 173-g. In addition, the side surface of the conductive alignment layer 123A is covered with the first nitride semiconductor layer 133A.

Each of the plurality of pixels 103A-p includes the conductive alignment layer 123A, the first nitride semiconductor layer 133A, the second nitride semiconductor layer 143, and the electrode layer 153 for an LED. Here, one of the electrodes of the LED is the conductive alignment layer 123A, and the other electrode of the LED is the electrode layer 153. The conductive alignment layer 123A is provided commonly in the plurality of pixels 103-p arranged in the first direction. On the other hand, the electrode layer 153 is provided in each of the plurality of pixels 103A-p arranged in a matrix. In the light emitting device 103A, a substrate on which a metal layer is formed, which is different from the substrate 113, is bonded to the substrate 113, and the plurality of electrode layers 153 are electrically connected to the metal layer.

Therefore, in the light emitting device 103A, light emission can be controlled using the plurality of pixels 103A-p arranged in the first direction as one unit.

### Fifth Embodiment

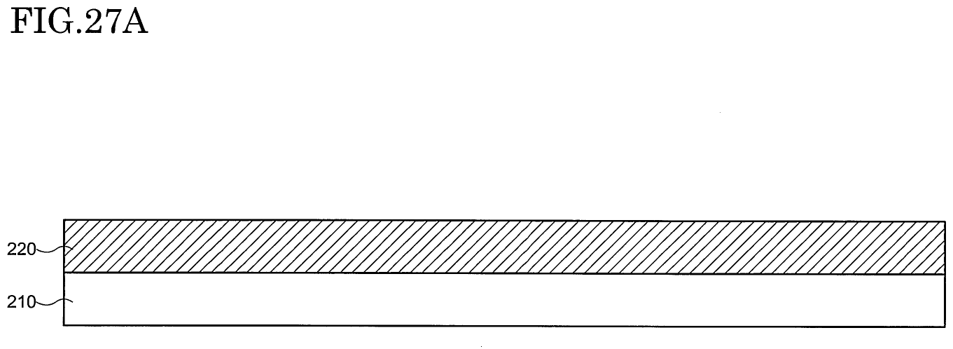

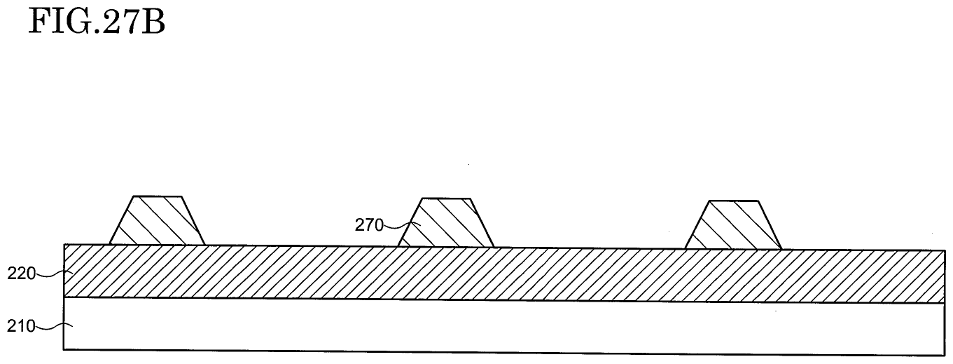

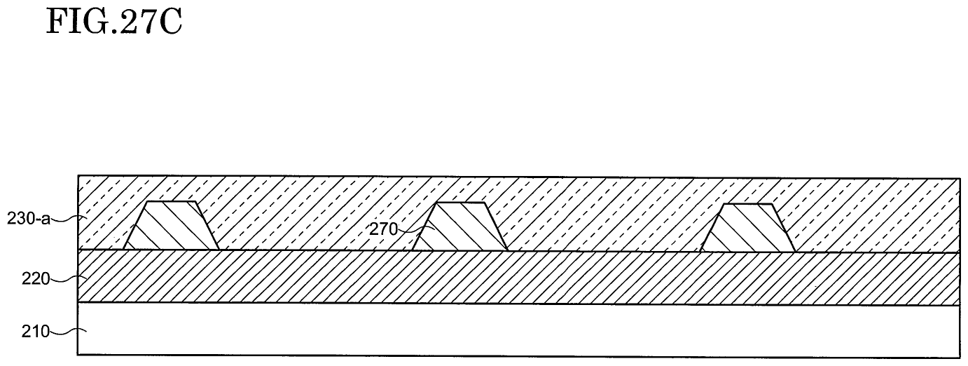

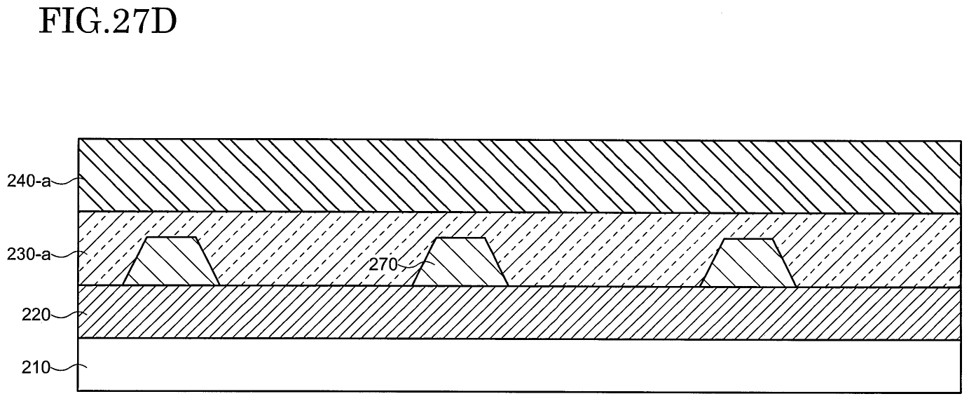

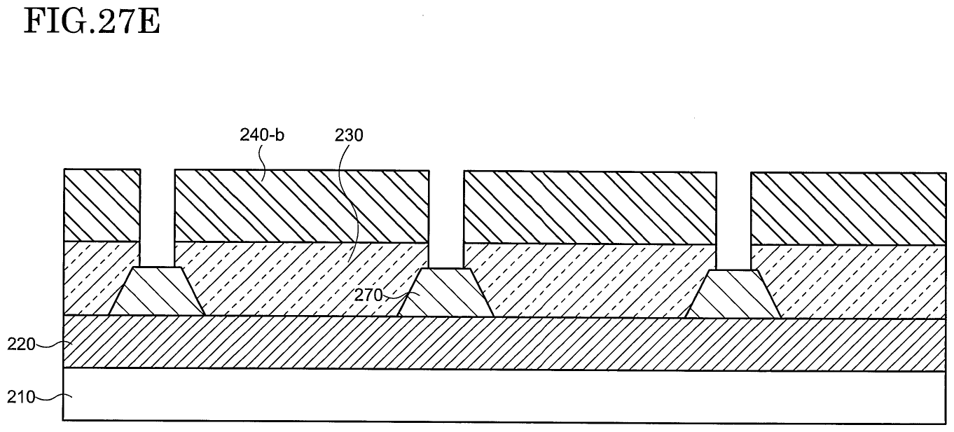

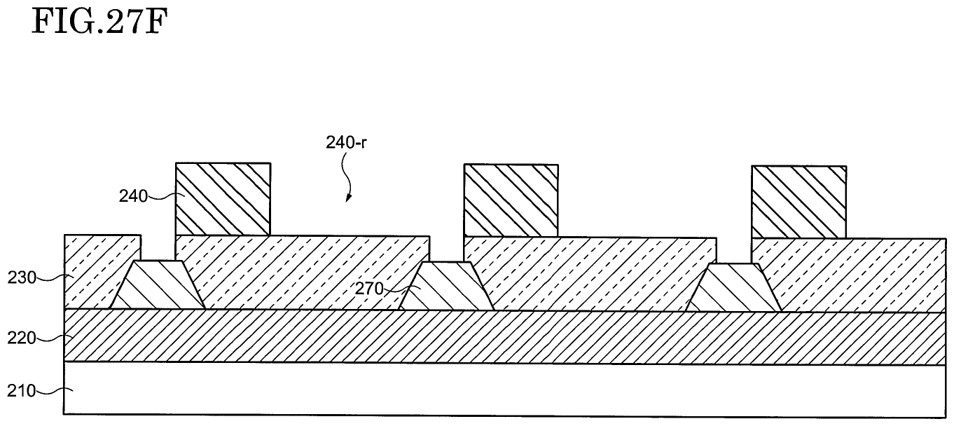

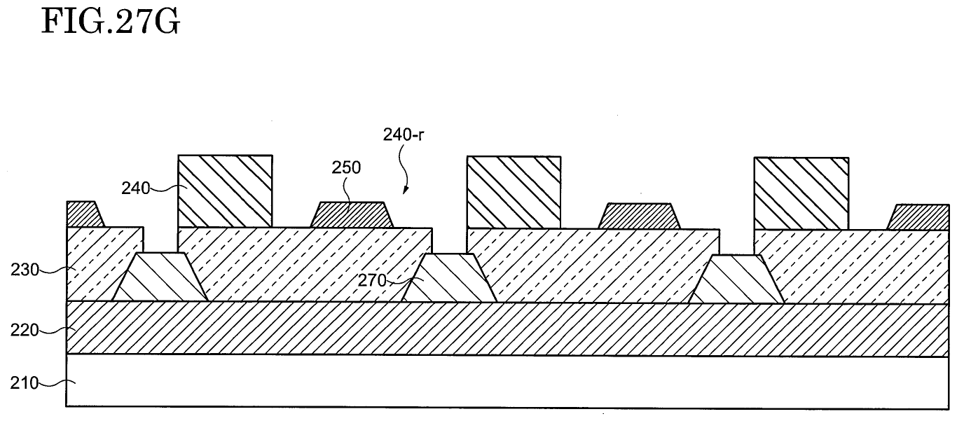

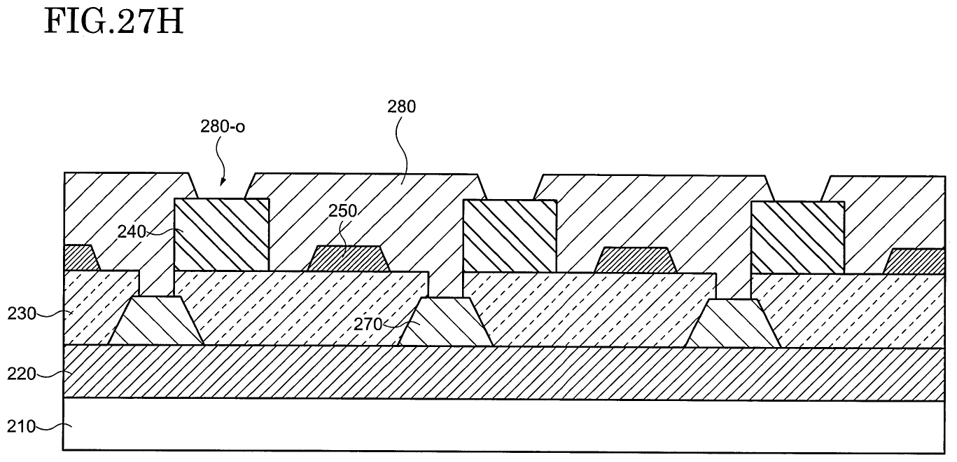

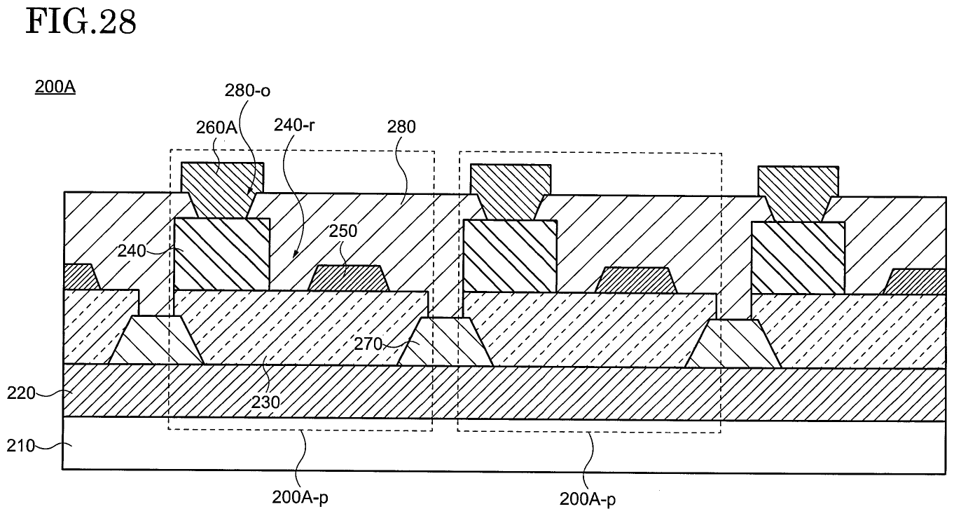

A light emitting device 200 according to an embodiment of the present invention is described with reference to FIG. 26 to FIG. 27H. In addition, when a configuration of the light emitting device 200 is similar to the configuration of the light emitting device 100, the description thereof may be omitted.

### 1. Configuration of Light Emitting Device 200

FIG. 26 is a schematic cross-sectional view showing a configuration of a light emitting device 200 according to an embodiment of the present invention. Specifically, FIG. 26 is a cross-sectional view of a pixel 200-p.

As shown in FIG. 26, the light emitting device 200 includes a substrate 210, an insulating alignment layer 220, a first nitride semiconductor layer 230, a second nitride semiconductor layer 240, a first electrode layer 250, a second electrode layer 260, a first rib 270, and a second rib 280.

The insulating alignment layer 220 is provided on the substrate 210. Further, the insulating alignment layer 220 is provided commonly in the plurality of pixels 200-p arranged in a matrix.

The first nitride semiconductor layer 230 and the second nitride semiconductor layer 240 are provided over the insulating alignment layer 220 in this order. Further, each of the first nitride semiconductor layer 230 and the second nitride semiconductor layer 240 is provided in an island shape in each of the plurality of pixels 200-p arranged in a matrix. The second nitride semiconductor layer 240 overlaps the first nitride semiconductor layer 230 and has a smaller area than the first nitride semiconductor layer 230 in a plan view. That is, the stack of the first nitride semiconductor layer 230 and the second nitride semiconductor layer 240 includes a recessed portion 240-r in which the first nitride semiconductor layer 230 is exposed.

The first electrode layer 250 is provided in the recessed portion 240-r and electrically connected to the first nitride semiconductor layer 230. Further, the first electrode layer 250 extends along the first direction and is provided commonly in a plurality of pixels 200-p arranged in the first direction. That is, the first electrode layer 250 is provided commonly in the plurality of pixels 200-p in one column.

The first rib 270 is provided on the insulating alignment layer 220 in a grid pattern. Further, the second rib 280 is provided over the nitride semiconductor layer 240, the first electrode layer 250, and the first rib 270 so as to cover the first nitride semiconductor layer 230, the second nitride semiconductor layer 240, and the first electrode layer 250. Furthermore, the second rib 280 includes an opening 280-o through which the second nitride semiconductor layer 240 is exposed. In addition, the plurality of pixels 200-p are partitioned by the first rib 270 and the second rib 280.

The second electrode layer 260 is provided on the second nitride semiconductor layer 240 and the second rib 280 so as to cover the opening 280-o. Further, the second electrode layer 260 is provided commonly in the plurality of pixels 200-p arranged in a matrix. Furthermore, the second electrode layer 260 is electrically connected to the second nitride semiconductor layer 240.

Details of each component of the light emitting device 200 are described in the following description.

Since the substrate 210 is similar to the substrate 110, the description thereof is omitted here.

The insulating alignment layer 220 can improve the crystallinity of the nitride semiconductor film formed on the insulating alignment layer 220, similar to the conductive alignment layer 120. However, unlike the conductive alignment layer 120, the insulating alignment layer 220 has an insulating property. For example, aluminum nitride (AlN), aluminum oxide (Al₂O₃), lithium niobate (LiNbO), BiLaTiO, SrFeO, SrFeO, BiFeO, BaFeO, ZnFeO, PMnN-PZT, bioapatite (BAp) or the like can be used for the insulating alignment layer 220. In particular, it is preferable to use aluminum nitride (AIN) for the insulating alignment layer 220.

The first nitride semiconductor layer 230 includes a first semiconductor layer of the LED. The first nitride semiconductor layer 230 on the insulating alignment layer 220 contains a nitride semiconductor and has a c-axis orientation with high crystallinity. In addition, the first nitride semiconductor layer 230 may include not only the first semiconductor layer but also a buffer layer containing undoped gallium nitride. When the first nitride semiconductor layer 230 is a stack of the buffer layer and the first semiconductor layer, the first semiconductor layer is stacked on the buffer layer so as to be in contact with the second nitride semiconductor layer 240.

Since the second nitride semiconductor layer 240 is similar to the second nitride semiconductor layer 140, the description thereof is omitted here.

Each of the first electrode layer 250 and the second electrode layer 260 functions as an electrode of the LED. For example, a transparent oxide such as indium tin oxide, indium zinc oxide, or zinc oxide can be used for each of the first electrode layer 250 and the second electrode layer 260. Further, metals such as indium, palladium, or gold can be used for the first electrode layer 250.

In the light emitting device 200, when the first semiconductor layer of the first nitride semiconductor layer 230 is an n-type semiconductor layer and the second semiconductor layer of the second nitride semiconductor layer 240 is a p-type semiconductor layer, the first electrode layer 250 and the second electrode layer 260 are an n-type electrode and a p-type electrode, respectively. On the other hand, when the first semiconductor layer of the first nitride semiconductor layer 230 is a p-type semiconductor layer and the second semiconductor layer of the second nitride semiconductor layer 240 is an n-type semiconductor layer, the first electrode layer 250 and the second electrode layer 260 are a p-type electrode and an n-type electrode, respectively.

Further, when emitting light is extracted from the bottom surface of the light emitting device 200 to the outside, it is preferable that the insulating alignment layer 220 has translucency or semitranslucency. On the other hand, when emitting light is extracted from the upper surface of the light emitting device 200, it is preferable that the second electrode layer 260 has translucency or semitranslucency.

Since the first rib 270 and the second rib 280 are similar to the first rib 160 and the second rib 170, respectively, the descriptions thereof are omitted here.

Each of the plurality of pixels 200-p includes the first electrode layer 250, the first nitride semiconductor layer 230, the second nitride semiconductor layer 240, and the second electrode layer 260 for an LED. Here, one of the electrodes of the LED is the first electrode layer 250, and the other electrode of the LED is the second electrode layer 260. The first electrode layer 250 is provided commonly in the plurality of pixels 200-p arranged in the first direction.

On the other hand, the second electrode layer 260 is provided commonly in the plurality of pixels 200-p arranged in a matrix. Therefore, in the light emitting device 200, light emission can be controlled using the plurality of pixels 200-p arranged in the first direction as one unit. In addition, the pixel 200-p may include the substrate 210 for convenience of explanation.

### 2. Manufacturing Method of Light Emitting Device 200

A method for manufacturing the light emitting device 200 according to an embodiment of the present invention is described with reference to FIG. 27A to FIG. 27H. FIG. 27A to FIG. 27H are schematic cross-sectional views showing the method of manufacturing the light emitting device 200 according to an embodiment of the present invention.

First, as shown in FIG. 27A, the insulating alignment layer 220 is formed on a substrate 210. The insulating alignment layer 220 can be formed using any method (apparatus) such as sputtering or CVD.

Next, as shown in FIG. 27B, the first rib 270 including an opening through which the insulating alignment layer 220 is exposed is formed on the insulating alignment layer 220. The first rib 270 is formed by depositing an inorganic or organic material and patterning the inorganic or organic material using photolithography.

Next, as shown in FIG. 27C, a first nitride semiconductor film 230-a is formed on the insulating alignment layer 220 and the first rib 270 so as to cover the opening of the first rib 270. The first nitride semiconductor film 230-a can be formed using sputtering. In the first nitride semiconductor film 230-a, a region in contact with the insulating alignment layer 220 has a c-axis orientation with high crystallinity.

Next, as shown in FIG. 27D, a second nitride semiconductor film 240-a is formed on the first nitride semiconductor film 230-a. The second nitride semiconductor film 240-a can be formed using sputtering. Since the second nitride semiconductor film 240-a is formed on the first nitride semiconductor film 230-a having the c-axis orientation with high crystallinity, the second nitride semiconductor film 240-a also has a c-axis orientation with high crystallinity, similar to the first nitride semiconductor film 230-a.

Next, as shown in FIG. 27E, the first nitride semiconductor film 230-a and the second nitride semiconductor film 240-a are patterned using photolithography to form the first nitride semiconductor layer 230 and a third nitride semiconductor film 240-b in an island shape.

Next, as shown in FIG. 27F, the third nitride semiconductor film 240-b is patterned using photolithography to form the recessed portion 240-r in which the first nitride semiconductor layer 230 is exposed. Further, the second nitride semiconductor layer 240 is formed by this patterning.

Next, as shown in FIG. 27G, the first electrode layer 250 is formed on the first nitride semiconductor layer 230 in the recessed portion 240-r. The first electrode layer 250 is formed by depositing a metal material and patterning the metal material using photolithography.

Next, as shown in FIG. 27H, the second rib 280 including the opening 280-o is provided on the upper surface of the second nitride semiconductor layer 240 so as to cover the first nitride semiconductor layer 230, the second nitride semiconductor layer 240, and the first electrode layer 250. The opening 280-o is formed using photolithography.

Finally, the second electrode layer 260 covering the opening 280-o and the second rib 280 is formed to manufacture the light emitting device 200 shown in FIG. 26.

In the light emitting device 200, since the first nitride semiconductor layer 230 is provided on the insulating alignment layer 220, the crystallinity of the first nitride semiconductor layer 230 is improved. Further, since the second nitride semiconductor layer 240 is provided on the first nitride semiconductor layer 230 with improved crystallinity, the crystallinity of the second nitride semiconductor layer 240 including the light emitting layer is also improved.

Therefore, the light emitting efficiency of the light emitting device 200 can be improved. Further, by providing the insulating alignment layer 220 on the substrate 210, it is possible to manufacture the plurality of light emitting devices 200 using a large-area amorphous substrate as the substrate 210.

### Modification 1 of Fifth Embodiment

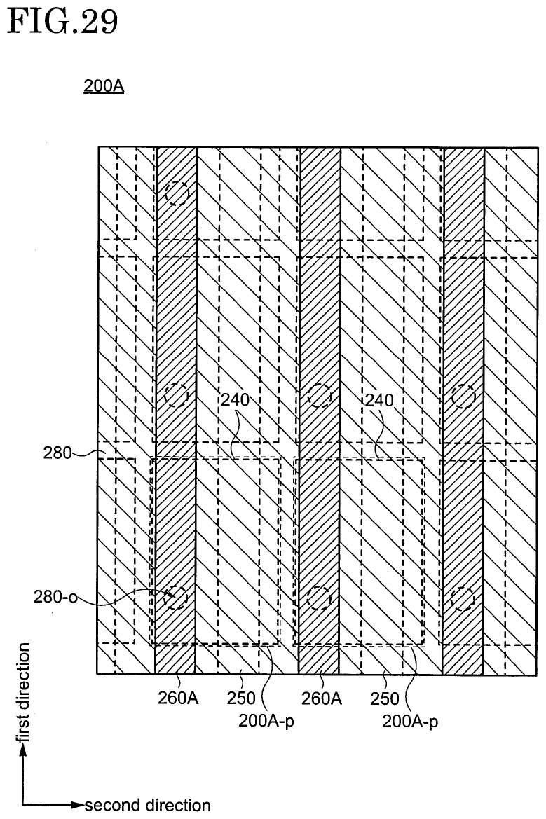

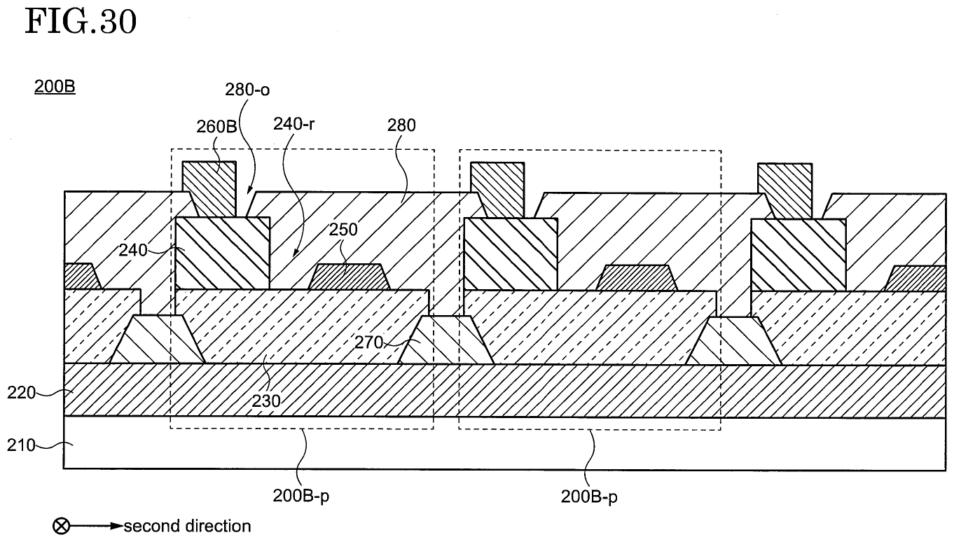

FIG. 28 and FIG. 29 are a schematic cross-sectional view and a schematic plan view showing a configuration of a light emitting device 200A according to an embodiment of the present invention. Specifically, FIG. 28 is a cross-sectional view of a pixel 200A-p. In addition, in FIG. 29, the second nitride semiconductor layer 240 and the first electrode layer 250 are shown by broken lines for convenience of explanation. The light emitting device 200A is one modification of the light emitting device 200. Therefore, when the configuration of the light emitting device 200A is similar to the configuration of the light emitting device 200, the description thereof may be omitted.

As shown in FIG. 28, the light emitting device 200A includes the substrate 210, the insulating alignment layer 220, the first nitride semiconductor layer 230, the second nitride semiconductor layer 240, the first electrode layer 250, a second electrode layer 260A, the first rib 270, and the second rib 280.

As shown in FIG. 29, the second electrode layer 260A extends along the first direction of the pixels 200A-p arranged in a matrix, and is provided commonly in a plurality of pixels 200A-p arranged in the first direction. That is, the second electrode layer 260A is provided commonly in the plurality of pixels 200A-p in one column. The second electrode layer 260A is in contact with the second nitride semiconductor layer 240 through the opening 280-o. Further, the second electrode layer 260A does not overlap the first electrode layer 250 in a plan view.

Each of the plurality of pixels 200A-p includes the first electrode layer 250, the first nitride semiconductor layer 230, the second nitride semiconductor layer 240, and the second electrode layer 260A for an LED. Here, one of the electrodes of the LED is the first electrode layer 250, and the other electrode of the LED is the second electrode layer 260A. The first electrode layer 250 and the second electrode layer 260A are provided commonly in the plurality of pixels 200A-p arranged in the first direction. Therefore, in the light emitting device 200A, light emission can be controlled using the plurality of pixels 200A-p arranged in the first direction as one unit.

### Modification 2 of Fifth Embodiment

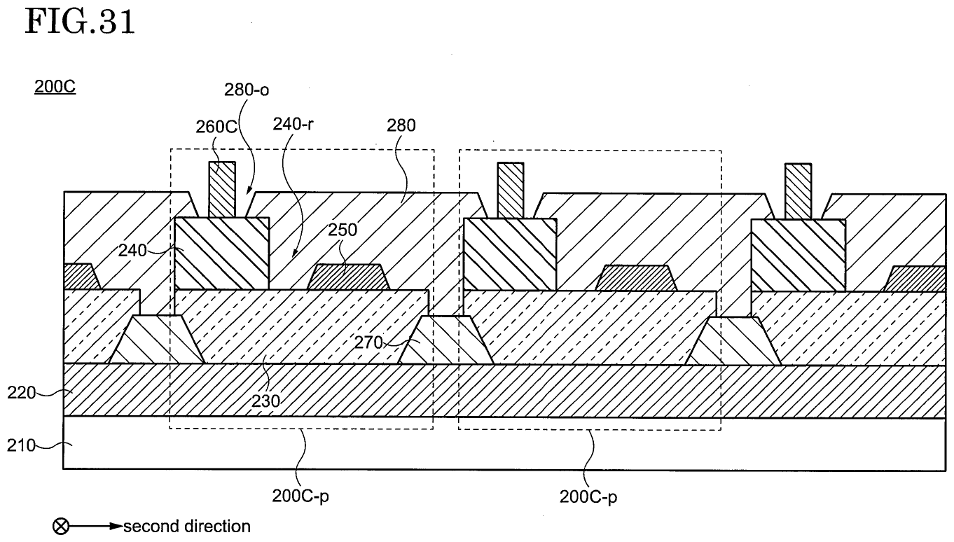

FIG. 30 is a schematic cross-sectional view showing a configuration of a light emitting device 200B according to an embodiment of the present invention. Specifically, FIG. 30 is a cross-sectional view of a pixel 200B-p. The light emitting device 200B is one modification of the light emitting device 200. Therefore, when the configuration of the light emitting device 200B is similar to the configuration of the light emitting device 200 or the light emitting device 200A, the description thereof may be omitted.

As shown in FIG. 30, the light emitting device 200B includes the substrate 210, the insulating alignment layer 220, the first nitride semiconductor layer 230, the second nitride semiconductor layer 240, the first electrode layer 250, a second electrode layer 260B, the first rib 270, and the second rib 280.

The second electrode layer 260B extends along the first direction of the pixels 200B-p arranged in a matrix, and is provided commonly in a plurality of pixels 200B-p arranged in the first direction, similar to the first electrode layer 250. That is, the second electrode layer 260B is provided commonly in the plurality of pixels 200B-p in one column. Although the second electrode layer 260B is in contact with the second nitride semiconductor layer 240 through the opening 280-o, the second electrode layer 260B does not completely cover the opening 280-o. Therefore, a part of the upper surface of the second nitride semiconductor layer 240 is exposed in the opening 280-o. Further, the second electrode layer 260B does not overlap the first electrode layer 250 in a plan view.

Each of the plurality of pixels 200B-p includes the first electrode layer 250, the first nitride semiconductor layer 230, the second nitride semiconductor layer 240, and the second electrode layer 260B for an LED. Here, one of the electrodes of the LED is the first electrode layer 250, and the other electrode of the LED is the second electrode layer 260B. The first electrode layer 250 and the second electrode layer 260B are provided commonly in the plurality of pixels 200B-p arranged in the first direction. Therefore, in the light emitting device 200B, light emission can be controlled using the plurality of pixels 200B-p arranged in the first direction as one unit.

Further, in the light emitting device 200B, a part of the second nitride semiconductor layer 240 is not covered with the second electrode layer 260B. Therefore, when the light emitting device 200B emits light in the upper surface direction, not only a transparent conductive material but also a non-transparent metal material can be used for the second electrode layer 260B. Furthermore, since light can be extracted from the opening 280-o, the light emitting efficiency of the light emitting device 200B is improved.

### Modification 3 of Fifth Embodiment

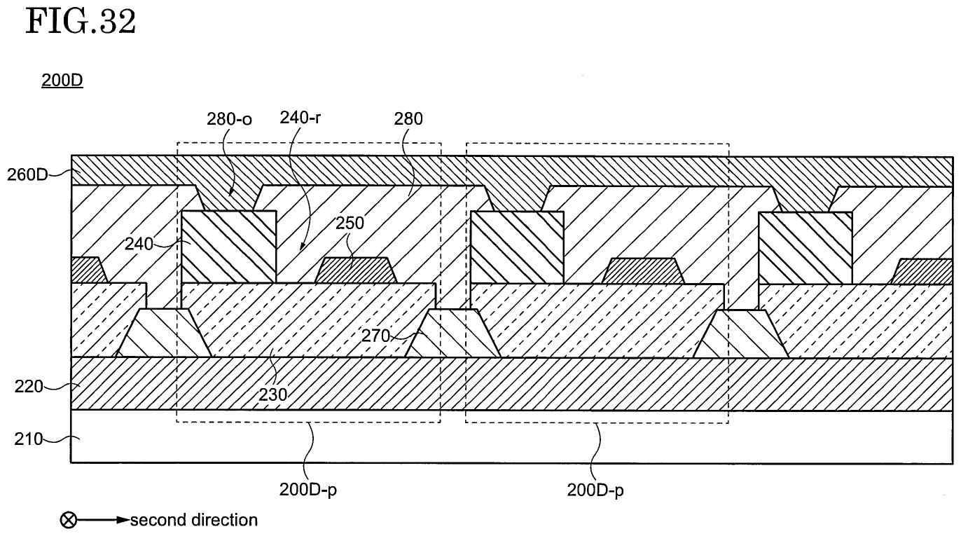

FIG. 31 is a schematic cross-sectional view showing a configuration of a light emitting device 200C according to an embodiment of the present invention. Specifically, FIG. 31 is a cross-sectional view of a pixel 200C-p. The light emitting device 200C is one modification of the light emitting device 200. Therefore, when the configuration of the light emitting device 200C is similar to the configurations of the light emitting devices 200 to 200B, the description thereof may be omitted.

As shown in FIG. 31, the light emitting device 200C includes the substrate 210, the insulating alignment layer 220, the first nitride semiconductor layer 230, the second nitride semiconductor layer 240, the first electrode layer 250, a second electrode layer 260C, the first rib 270, and the second rib 280.

The second electrode layer 260C extends along the first direction of the pixels 200C-p arranged in a matrix, and is provided commonly in a plurality of pixels 200C-p arranged in the first direction, similar to the first electrode layer 250. That is, the second electrode layer 260C is provided commonly in the plurality of pixels 200C-p in one column. Although the second electrode layer 260C is in contact with the second nitride semiconductor layer 240 through the opening 280-o, the second electrode layer 260C does not completely cover the opening 280-o. Therefore, a part of the upper surface of the second nitride semiconductor layer 240 is exposed in the opening 280-o. Further, in the second direction orthogonal to the first direction, the width of the second electrode layer 260C is smaller than the maximum width of the opening 280-o. Furthermore, the second electrode layer 260C does not overlap the first electrode layer 250 in a plan view.

Each of the plurality of pixels 200C-p includes the first electrode layer 250, the first nitride semiconductor layer 230, the second nitride semiconductor layer 240, and the second electrode layer 260C for an LED. Here, one of the electrodes of the LED is the first electrode layer 250, and the other electrode of the LED is the second electrode layer 260C. The first electrode layer 250 and the second electrode layer 260C are provided commonly in the plurality of pixels 200C-p arranged in the first direction. Therefore, in the light emitting device 200C, light emission can be controlled using the plurality of pixels 200C-p arranged in the first direction as one unit.

Further, in the light emitting device 200C, a part of the second nitride semiconductor layer 240 is not covered with the second electrode layer 260C.

Therefore, when the light emitting device 200C emits light in the upper surface direction, not only a transparent conductive material but also a non-transparent metal material can be used for the second electrode layer 260C. Furthermore, since light can be extracted from the opening 280-o, the light emitting efficiency of the light emitting device 200C is improved.

### Modification 4 of Fifth Embodiment

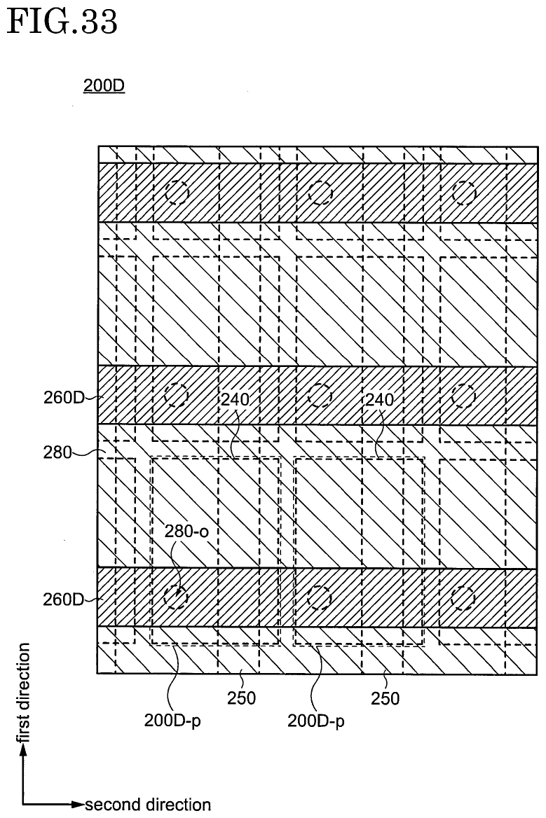

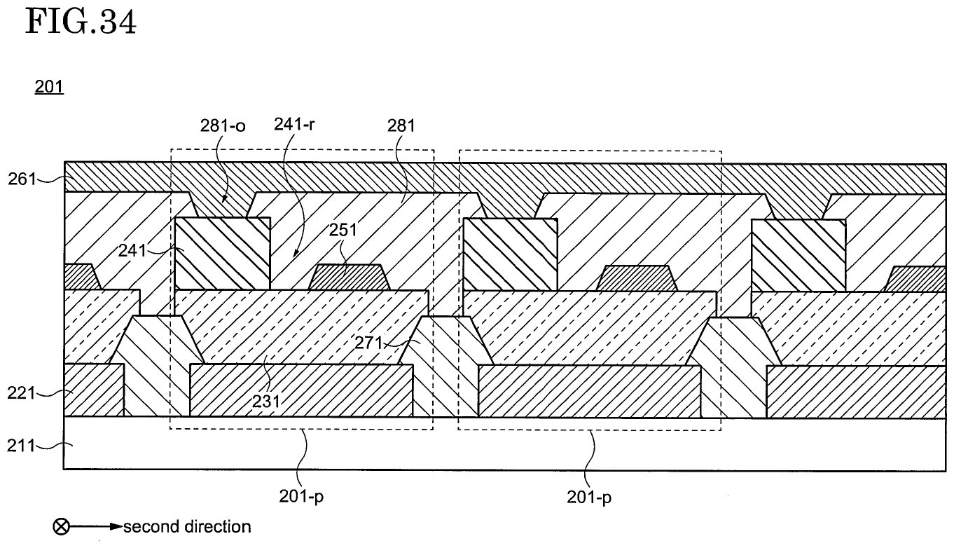

FIG. 32 and FIG, 33 are a schematic cross-sectional view and a schematic plan view showing a configuration of a light emitting device 200D according to an embodiment of the present invention. Specifically, FIG. 32 is a cross-sectional view of a pixel 200D-p. In addition, in FIG. 33, the second nitride semiconductor layer 240 and the first electrode layer 250 are shown by broken lines for convenience of explanation. The light emitting device 200D is one modification of the light emitting device 200. Therefore, when the configuration of the light emitting device 200D is similar to the configurations of the light emitting devices 200 to 200C, the description thereof may be omitted.

As shown in FIG. 32, the light emitting device 200 includes the substrate 210, the insulating alignment layer 220, the first nitride semiconductor layer 230, the second nitride semiconductor layer 240, the electrode layer 250, a second electrode layer 260D, the first rib 270, and the second rib 280.

As shown in FIG. 33, the second electrode layer 260D extends along the second direction orthogonal to the first direction, and is provided commonly in a plurality of pixels 200D-p arranged in the second direction. That is, the second electrode layer 260D is provided commonly in the plurality of pixels 200D-p in one row. The second electrode layer 260D is in contact with the second nitride semiconductor layer 240 through the opening 280-o. Further, although the second electrode layer 260D intersects with the first electrode layer 250 in a plan view, the second electrode layer 260D is separated from the first electrode layer 250 by the second rib 280.

Each of the plurality of pixels 200D-p includes the first electrode layer 250, the first nitride semiconductor layer 230, the second nitride semiconductor layer 240, and the second electrode layer 260D for an LED. Here, one of the electrodes of the LED is the first electrode layer 250, and the other electrode of the LED is the second electrode layer 260D. The first electrode layer 250 is provided commonly in the plurality of pixels 200D-p arranged in the first direction. On the other hand, the second electrode layer 260D is provided commonly in the plurality of pixels 200D-p arranged in the second direction.

Therefore, in the light emitting device 200D, light emission of the pixel 200D-p at the intersection of the first electrode layer 250 and the second electrode layer 260 can be controlled. That is, in the light emitting device 200D, the light emission of the pixels 200D-p can be controlled by passive driving.

### Sixth Embodiment

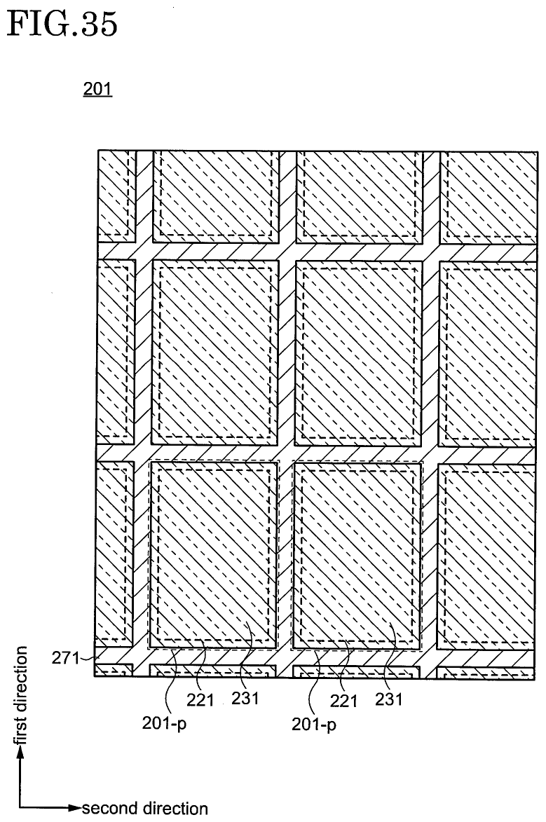

A light emitting device 201 according to an embodiment of the present invention is described with reference to FIG. 34 and FIG. 35. In addition, when a configuration of the light emitting device 201 is similar to the configuration of the light emitting device 200, the description thereof may be omitted.

FIG. 34 is a schematic cross-sectional view showing a configuration of the light emitting device 201 according to an embodiment of the present invention. Specifically, FIG. 34 is a cross-sectional view of a pixel 201-p. Further, FIG. 35 is a schematic plan view showing a configuration of the light emitting device 201 according to an embodiment of the present invention. In addition, only the insulating alignment layer 221, the first nitride semiconductor layer 231, and the first rib 271 are shown in FIG. 35 for convenience of explanation.

As shown in FIG. 34, the light emitting device 201 includes a substrate 211, an insulating alignment layer 221, a first nitride semiconductor layer 231, a second nitride semiconductor layer 241, a first electrode layer 251, a second electrode layer 261, a first rib 271, and a second rib 281.

The insulating alignment layer 221 is provided on the substrate 211. Further, as shown in FIG. 35, the insulating alignment layer 221 is provided in an island shape in each of the plurality of pixels 201-p arranged in a matrix.

The first nitride semiconductor layer 231 and the second nitride semiconductor layer 241 are provided over the insulating alignment layer 221 in this order. Further, each of the first nitride semiconductor layer 231 and the second nitride semiconductor layer 241 is provided in an island shape in each of the plurality of pixels 201-p arranged in a matrix. The second nitride semiconductor layer 241 overlaps the first nitride semiconductor layer 231 and has a smaller area than the first nitride semiconductor layer 231 in a plan view. That is, the stack of the first nitride semiconductor layer 231 and the second nitride semiconductor layer 241 includes a recessed portion 241-r in which the first nitride semiconductor layer 231 is exposed.

The first electrode layer 251 is provided in the recessed portion 241-r and electrically connected to the first nitride semiconductor layer 231. Further, the first electrode layer 251 extends along the first direction and is provided commonly in a plurality of pixels 201-p arranged in the first direction. That is, the first electrode layer 251 is provided commonly in the plurality of pixels 201-p in one column.

The first rib 271 is provided in a grid pattern on the substrate 211 so as to fill a groove portion between the insulating alignment layers 221. Further, the second rib 281 is provided on the nitride semiconductor layer 241, the first electrode layer 251, and the first rib 271 so as to cover the first nitride semiconductor layer 231, the second nitride semiconductor layer 241, and the first electrode layer 251. Further, the second rib 281 includes an opening 281-o through which the second nitride semiconductor layer 241 is exposed. In addition, the plurality of pixels 201-p are partitioned by the first rib 271 and the second rib 281.

The second electrode layer 261 is provided on the second nitride semiconductor layer 241 and the second rib 281 so as to cover the opening 281-o. Further, the second electrode layer 261 is provided commonly in the plurality of pixels 201-p arranged in a matrix. Furthermore, the second electrode layer 261 is electrically connected to the second nitride semiconductor layer 241.

Each of the plurality of pixels 201-p includes the first electrode layer 251, the first nitride semiconductor layer 231, the second nitride semiconductor layer 241, and the second electrode layer 261 for an LED. Here, one of the electrodes of the LED is the first electrode layer 251, and the other electrode of the LED is the second electrode layer 261. The first electrode layer 251 is provided commonly in the plurality of pixels 201-p arranged in the first direction. On the other hand, the second electrode layer 261 is provided commonly in the plurality of pixels 201-p arranged in a matrix. Therefore, in the light emitting device 201, light emission can be controlled using the plurality of pixels 201-p arranged in the first direction as one unit. In addition, the pixel 201-p may include the substrate 211 for convenience of explanation.

In the light emitting device 201, since the first nitride semiconductor layer 231 is provided on the insulating alignment layer 221, the crystallinity of the first nitride semiconductor layer 231 is improved. Further, since the second nitride semiconductor layer 241 is provided on the first nitride semiconductor layer 231 with improved crystallinity, the crystallinity of the second nitride semiconductor layer 241 including the light emitting layer is also improved. Therefore, the light emitting efficiency of the light emitting device 201 can be improved. Furthermore, by providing the insulating alignment layer 221 on the substrate 211, it is possible to manufacture the plurality of light emitting devices 201 using a large-area amorphous substrate as the substrate 211.

### Modification 1 of Sixth Embodiment

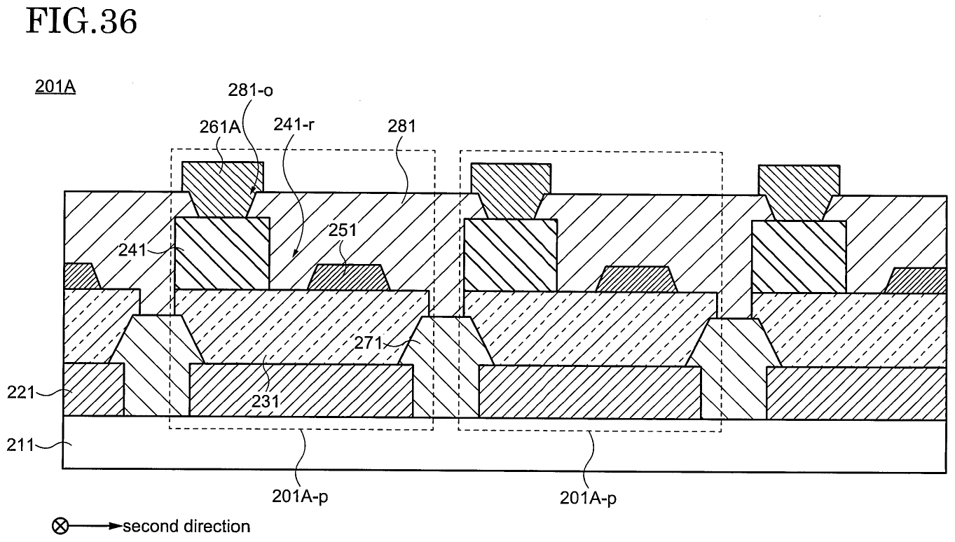

FIG. 36 is a schematic cross-sectional view showing a configuration of a light emitting device 201A according to an embodiment of the present invention. Specifically, FIG. 36 is a cross-sectional view of a pixel 201A-p. The light emitting device 201A is one modification of the light emitting device 201. Therefore, when the configuration of the light emitting device 201A is similar to the configuration of the light emitting device 201, the description thereof may be omitted.

As shown in FIG. 36, the light emitting device 201A includes the substrate 211, the insulating alignment layer 221, the first nitride semiconductor layer 231, the second nitride semiconductor layer 241, the first electrode layer 251, a second electrode layer 261A, the first rib 271, and the second rib 281.

The second electrode layer 261A extends along the first direction of the pixels 201A-p arranged in a matrix, and is provided commonly in a plurality of pixels 201A-p arranged in the first direction, similar to the first electrode layer 251. That is, the second electrode layer 261A is provided commonly in the plurality of pixels 201A-p in one column. The second electrode layer 261A is in contact with the second nitride semiconductor layer 241 through the opening 281-o. Further, the second electrode layer 261A does not overlap the first electrode layer 251 in a plan view.

Each of the plurality of pixels 201A-p includes the first electrode layer 251, the first nitride semiconductor layer 231, the second nitride semiconductor layer 241, and the second electrode layer 261A for an LED. Here, one of the electrodes of the LED is the first electrode layer 251, and the other electrode of the LED is the second electrode layer 261A. The first electrode layer 251 and the second electrode layer 261A are provided commonly in the plurality of pixels 201A-p arranged in the first direction. Therefore, in the light emitting device 201A, light emission can be controlled using the plurality of pixels 201A-p arranged in the first direction as one unit.

### Modification 2 of Sixth Embodiment

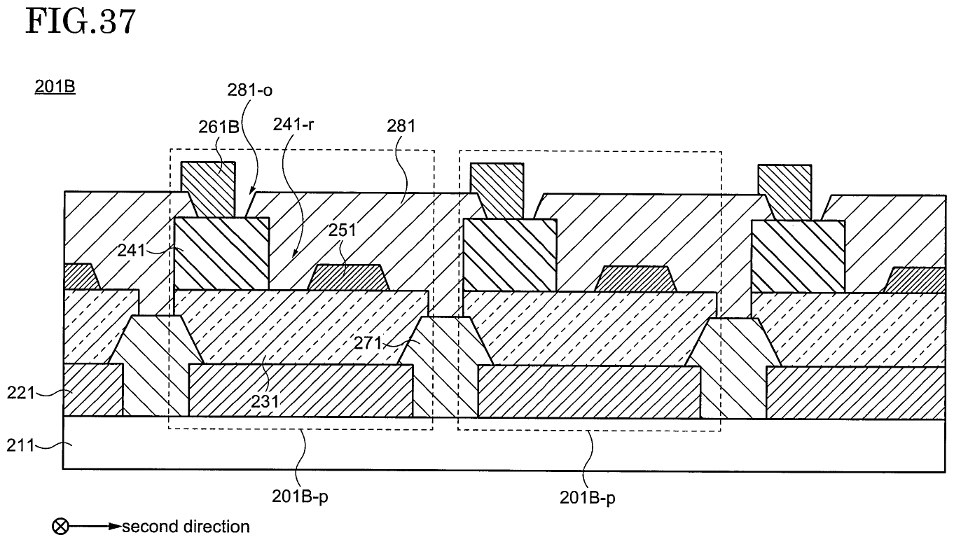

FIG. 37 is a schematic cross-sectional view showing a configuration of a light emitting device 201B according to an embodiment of the present invention. Specifically, FIG. 37 is a cross-sectional view of a pixel 201B-p. The light emitting device 201B is one modification of the light emitting device 201. Therefore, when the configuration of the light emitting device 201B is similar to the configuration of the light emitting device 201 or the light emitting device 201A, the description thereof may be omitted.

As shown in FIG. 37, the light emitting device 201B includes the substrate 211, the insulating alignment layer 221, the first nitride semiconductor layer 231, the second nitride semiconductor layer 241, the first electrode layer 251, a second electrode layer 261B, the first rib 271, and the second rib 281.

The second electrode layer 261B extends along the first direction of the pixels 201B-p arranged in a matrix, and is provided commonly in a plurality of pixels 201B-p arranged in the first direction, similar to the first electrode layer 251. That is, the second electrode layer 261B is provided commonly in the plurality of pixels 201B-p in one column. Although the second electrode layer 261B is contact with the second nitride semiconductor layer 241 through the opening 281-o, the second electrode layer 261B does not completely cover the opening 281-o. Therefore, a part of the upper surface of the second nitride semiconductor layer 241 is exposed in the opening 281-o. Further, the second electrode layer 261B does not overlap the first electrode layer 251 in a plan view.

Each of the plurality of pixels 201B-p includes the first electrode layer 251, the first nitride semiconductor layer 231, the second nitride semiconductor layer 241, and the second electrode layer 261B for an LED. Here, one of the electrodes of the LED is the first electrode layer 251, and the other electrode of the LED is the electrode layer 261B. The first electrode layer 251 and the second electrode layer 261B are provided commonly in the plurality of pixels 201B-p arranged in the first direction. Therefore, in the light emitting device 201B, light emission can be controlled using the plurality of pixels 201B-p arranged in the first direction as one unit.

Further, in the light emitting device 201B, a part of the second nitride semiconductor layer 241 is not covered with the second electrode layer 261B. Therefore, when the light emitting device 201B emits light in the upper surface direction, not only a transparent conductive material but also a non-transparent metal material can be used for the second electrode layer 261B. Furthermore, since light can be extracted from the opening 281-o, the light emitting efficiency of the light emitting device 201B is improved.

### Modification 3 of Sixth Embodiment

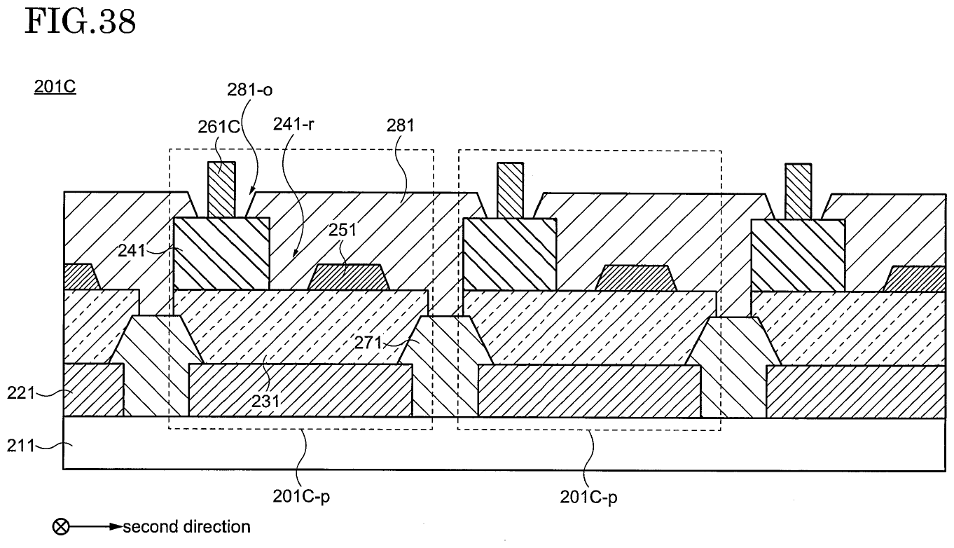

FIG. 38 is a schematic cross-sectional view showing a configuration of a light emitting device 201C according to an embodiment of the present invention. Specifically, FIG. 38 is a cross-sectional view of a pixel 201C-p. The light emitting device 201C is one modification of the light emitting device 201. Therefore, when the configuration of the light emitting device 201C is similar to the configurations of the light emitting devices 201 to 201B, the description thereof may be omitted.

As shown in FIG. 38, the light emitting device 2010 includes the substrate 211, the insulating alignment layer 221, the first nitride semiconductor layer 231, the second nitride semiconductor layer 241, the first electrode layer 251, a second electrode layer 261C, the first rib 271, and the second rib 281.

The second electrode layer 261C extends along the first direction of the pixels 201C-p arranged in a matrix, and is provided commonly in a plurality of pixels 201C-p arranged in the first direction, similar to the first electrode layer 251. That is, the second electrode layer 261C is provided commonly in the plurality of pixels 201C-p in one column. Although the second electrode layer 261C is in contact with the second nitride semiconductor layer 241 through the opening 281-o, the second electrode layer 261C does not completely cover the opening 281-o. Therefore, a part of the upper surface of the second nitride semiconductor layer 241 is exposed in the opening 281-o. Further, in the second direction orthogonal to the first direction, the width of the second electrode layer 261C is smaller than the maximum width of the opening 281-o. Furthermore, the second electrode layer 261C does not overlap the first electrode layer 251 in a plan view.

Each of the plurality of pixels 201C-p includes the first electrode layer 251, the first nitride semiconductor layer 231, the second nitride semiconductor layer 241, and the second electrode layer 261C for an LED. Here, one of the electrodes of the LED is the first electrode layer 251, and the other electrode of the LED is the second electrode layer 261C. The first electrode layer 251 and the second electrode layer 261C are provided commonly in the plurality of pixels 201C-p arranged in the first direction. Therefore, in the light emitting device 201C, light emission can be controlled using the plurality of pixels 201C-p arranged in the first direction as one unit.

Further, in the light emitting device 201C, a part of the second nitride semiconductor layer 241 is not covered with the second electrode layer 261C. Therefore, when the light emitting device 201C emits light in the upper surface direction, not only a transparent conductive material but also a non-transparent metal material can be used for the second electrode layer 261C. Furthermore, since light can be extracted from the opening 281-o, the light emitting efficiency of the light emitting device 201C is improved.

### Seventh Embodiment

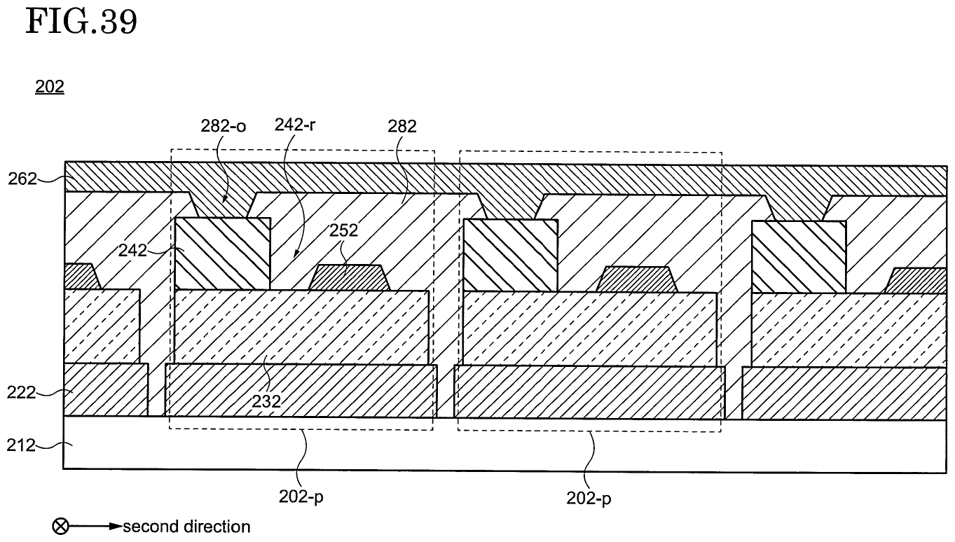

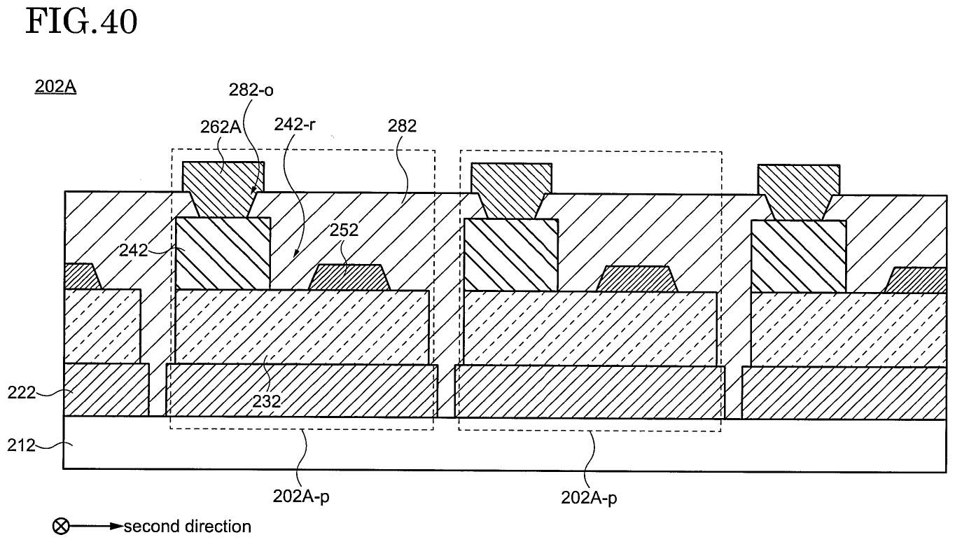

A light emitting device 202 according to an embodiment of the present invention is described with reference to FIG. 39. In addition, when a configuration of the light emitting device 202 is similar to the configuration of the light emitting device 200 or the light emitting device 201, the description thereof may be omitted.

FIG. 39 is a schematic cross-sectional view showing a configuration of the light emitting device 202 according to an embodiment of the present invention. Specifically, FIG. 39 is a cross-sectional view of a pixel 202-p.

As shown in FIG. 39, the light emitting device 202 includes a substrate 212, an insulating alignment layer 222, a first nitride semiconductor layer 232, a second nitride semiconductor layer 242, a first electrode layer 252, a second electrode layer 262, and a rib 282.

The insulating alignment layer 222 is provided on the substrate 212. Further, the insulating alignment layer 222 is provided in an island shape in each of the plurality of pixels 202-p arranged in a matrix.

The first nitride semiconductor layer 232 and the second nitride semiconductor layer 242 are provided over the insulating alignment layer 222 in this order. Further, each of the first nitride semiconductor layer 232 and the second nitride semiconductor layer 242 is provided in an island shape in each of the plurality of pixels 202-p arranged in a matrix. The second nitride semiconductor layer 242 overlaps the first nitride semiconductor layer 232 and has a smaller area than the first nitride semiconductor layer 232 in a plan view. That is, the stack of the first nitride semiconductor layer 232 and the second nitride semiconductor layer 242 includes a recessed portion 242-r in which the first nitride semiconductor layer 232 is exposed.

The first electrode layer 252 is provided in the recessed portion 242-r and electrically connected to the first nitride semiconductor layer 232. Further, the first electrode layer 252 extends along the first direction and is provided commonly in a plurality of pixels 202-p arranged in the first direction. That is, the first electrode layer 252 is provided commonly in the plurality of pixels 202-p in one column. Therefore, in the first direction, the first electrode layer 252 is in contact with not only the top surface of the first nitride semiconductor layer 232 but also the side surface of the first nitride semiconductor layer 232.

The ribs 282 is provided in a grid pattern on the substrate 212 so as to cover the first nitride semiconductor layer 232, the second nitride semiconductor layer 242, and the first electrode layer 252 and fill in a groove portion between the insulating alignment layer 222 and the first nitride semiconductor layer 232. Further, the rib 282 includes an opening 282-o through which the second nitride semiconductor layer 242 is exposed. In addition, the plurality of pixels 202-p are partitioned by the rib 282.

The second electrode layer 262 is provided on the second nitride semiconductor layer 242 and the rib 282 so as to cover the opening 282-o. Further, the second electrode layer 262 is provided commonly in the pixels 202-p arranged in a matrix. Furthermore, the second electrode layer 262 is electrically connected to the second nitride semiconductor layer 242.

Each of the plurality of pixels 202-p includes the first electrode layer 252, the first nitride semiconductor layer 232, the second nitride semiconductor layer 242, and the second electrode layer 262 for an LED. Here, one of the electrodes of the LED is the first electrode layer 252, and the other electrode of the LED is the second electrode layer 262. The first electrode layer 252 is provided commonly in the plurality of pixels 202-p arranged in the first direction. On the other hand, the second electrode layer 262 is provided commonly in the plurality of pixels 202-p arranged in a matrix. Therefore, in the light emitting device 202, light emission can be controlled using the plurality of pixels 202-p arranged in the first direction as one unit. In addition, the pixel 202-p may include the substrate 212 for convenience of explanation.

In the light emitting device 202, since the first nitride semiconductor layer 232 is provided on the insulating alignment layer 222, the crystallinity of the first nitride semiconductor layer 232 is improved. Further, since the second nitride semiconductor layer 242 is provided on the first nitride semiconductor layer 232 with improved crystallinity, the crystallinity of the second nitride semiconductor layer 242 including the light emitting layer is also improved.

Therefore, the light emitting efficiency of the light emitting device 202 can be improved. Further, by providing the insulating alignment layer 222 on the substrate 212, it is possible to manufacture the plurality of light emitting devices 202 using a large-area amorphous substrate as the substrate 212.

### Modification 1 of Seventh Embodiment

FIG. 40 is a schematic cross-sectional view showing a configuration of a light emitting device 202A according to an embodiment of the present invention. Specifically, FIG. 40 is a cross-sectional view of a pixel 202A-p. The light emitting device 202A is one modification of the light emitting device 202. Therefore, when the configuration of the light emitting device 202A is similar to the configuration of the light emitting device 202, the description thereof may be omitted.

As shown in FIG. 40, the light emitting device 202A includes the substrate 212, the insulating alignment layer 222, the first nitride semiconductor layer 232, the second nitride semiconductor layer 242, the first electrode layer 252, a second electrode layer 262A, and the rib 282.

The second electrode layer 262A extends along the first direction of the pixels 202A-p arranged in a matrix, and is provided commonly in a plurality of pixels 202A-p arranged in the first direction, similar to the first electrode layer 252. That is, the second electrode layer 262A is provided commonly in the plurality of pixels 202A-p in one column. The second electrode layer 262A is in contact with the second nitride semiconductor layer 242 through the opening 282-o. Further, the second electrode layer 262A does not overlap the first electrode layer 252 in a plan view.

Each of the plurality of pixels 202A-p includes the first electrode layer 252, the first nitride semiconductor layer 232, the second nitride semiconductor layer 242, and the second electrode layer 262A for an LED. Here, one of the electrodes of the LED is the first electrode layer 252, and the other electrode of the LED is the second electrode layer 262A. The first electrode layer 252 and the second electrode layer 262A are provided commonly in the plurality of pixels 202A-p arranged in the first direction. Therefore, in the light emitting device 202A, light emission can be controlled using the plurality of pixels 202A-p arranged in the first direction as one unit.

### Modification 2 of Seventh Embodiment

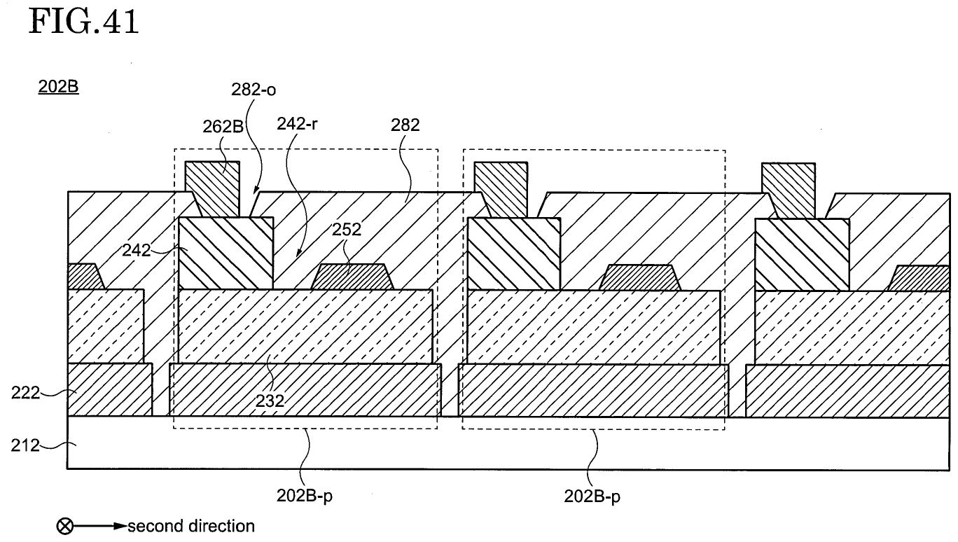

FIG. 41 is a schematic cross-sectional view showing a configuration of a light emitting device 202B according to an embodiment of the present invention. Specifically, FIG. 41 is a cross-sectional view of a pixel 202B-p. The light emitting device 202B is one modification of the light emitting device 202. Therefore, when the configuration of the light emitting device 202B is similar to the configuration of the light emitting device 202 or the light emitting device 202A, the description thereof may be omitted.

As shown in FIG. 41, the light emitting device 202B includes the substrate 212, the insulating alignment layer 222, the first nitride semiconductor layer 232, the second nitride semiconductor layer 242, the first electrode layer 252, a second electrode layer 262B, and the rib 282.

The second electrode layer 262B extends along the first direction of the pixels 202B-p arranged in a matrix, and is provided commonly in a plurality of pixels 201B-p arranged in the first direction, similar to the first electrode layer 252. That is, the second electrode layer 262B is provided commonly in the plurality of pixels 202B-p in one column. Although the second electrode layer 262B is in contact with the second nitride semiconductor layer 242 through the opening 282-o, the second electrode layer 262B does not completely cover the opening 282-o. Therefore, a part of the upper surface of the second nitride semiconductor layer 242 is exposed in the opening 282-o. Further, the second electrode layer 262B does not overlap the first electrode layer 252 in a plan view.

Each of the plurality of pixels 202B-p includes the first electrode layer 252, the first nitride semiconductor layer 232, the second nitride semiconductor layer 242, and the second electrode layer 262B for an LED. Here, one of the electrodes of the LED is the first electrode layer 252, and the other electrode of the LED is the second electrode layer 262B. The first electrode layer 252 and the second electrode layer 262B are provided commonly in the plurality of pixels 202B-p arranged in the first direction. Therefore, in the light emitting device 202B, light emission can be controlled using the plurality of pixels 202B-p arranged in the first direction as one unit.

Further, in the light emitting device 202B, a part of the second nitride semiconductor layer 242 is not covered with the second electrode layer 262B. Therefore, when the light emitting device 202B emits light in the upper surface direction, not only a transparent conductive material but also a non-transparent metal material can be used for the second electrode layer 262B. Furthermore, since light can be extracted from the opening 282-o, the light emitting efficiency of the light emitting device 202B is improved.

### Modification 3 of Seventh Embodiment

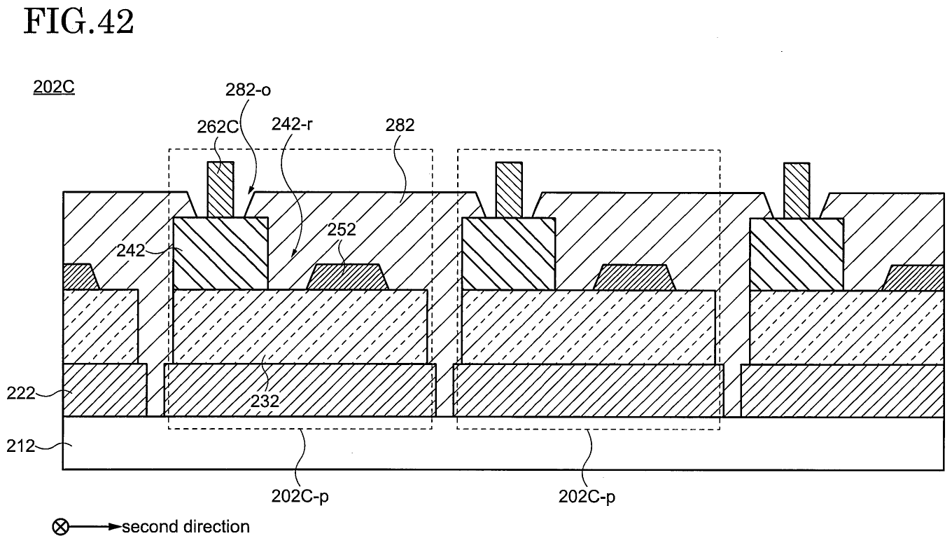

FIG. 42 is a schematic cross-sectional view showing a configuration of a light emitting device 202C according to an embodiment of the present invention. Specifically, FIG. 42 is a cross-sectional view of a pixel 202C-p. The light emitting device 202C is one modification of the light emitting device 202. Therefore, when the configuration of the light emitting device 202C is similar to the configurations of the light emitting devices 202 to 202B, the description thereof may be omitted.

As shown in FIG. 42, the light emitting device 202C includes the substrate 212, the insulating alignment layer 222, the first nitride semiconductor layer 232, the second nitride semiconductor layer 242, the first electrode layer 252, a second electrode layer 262C, and the rib 282.

The second electrode layer 262C extends along the first direction of the pixels 202C-p arranged in a matrix, and is provided commonly in a plurality of pixels 202C-p arranged in the first direction, similar to the first electrode layer 252. That is, the second electrode layer 262C is provided commonly in the plurality of pixels 202C-p in one column. Although the second electrode layer 262C is in contact with the second nitride semiconductor layer 242 through the opening 282-o, the second electrode layer 262C does not completely cover the opening 282-o. Therefore, a part of the upper surface of the second nitride semiconductor layer 242 is exposed in the opening 282-o. Further, in the second direction orthogonal to the first direction, the width of the second electrode layer 262C is smaller than the maximum width of the opening 282-o.

Furthermore, the second electrode layer 262C does not overlap the first electrode layer 252 in a plan view.

Each of the plurality of pixels 202C-p includes the first electrode layer 252, the first nitride semiconductor layer 232, the second nitride semiconductor layer 242, and the second electrode layer 262C for an LED. Here, one of the electrodes of the LED is the first electrode layer 252, and the other electrode of the LED is the second electrode layer 262C. The first electrode layer 252 and the second electrode layer 262C are provided commonly in the plurality of pixels 202C-p arranged in the first direction. Therefore, in the light emitting device 202C, light emission can be controlled using the plurality of pixels 202C-p arranged in the first direction as one unit.

Further, in the light emitting device 202C, a part of the second nitride semiconductor layer 242 is not covered with the second electrode layer 262C. Therefore, when the light emitting device 202C emits light in the upper surface direction, not only a transparent conductive material but also a non-transparent metal material can be used for the second electrode layer 262C. Furthermore, since light can be extracted from the opening 282-o, the light emitting efficiency of the light emitting device 202C is improved.

### Eighth Embodiment

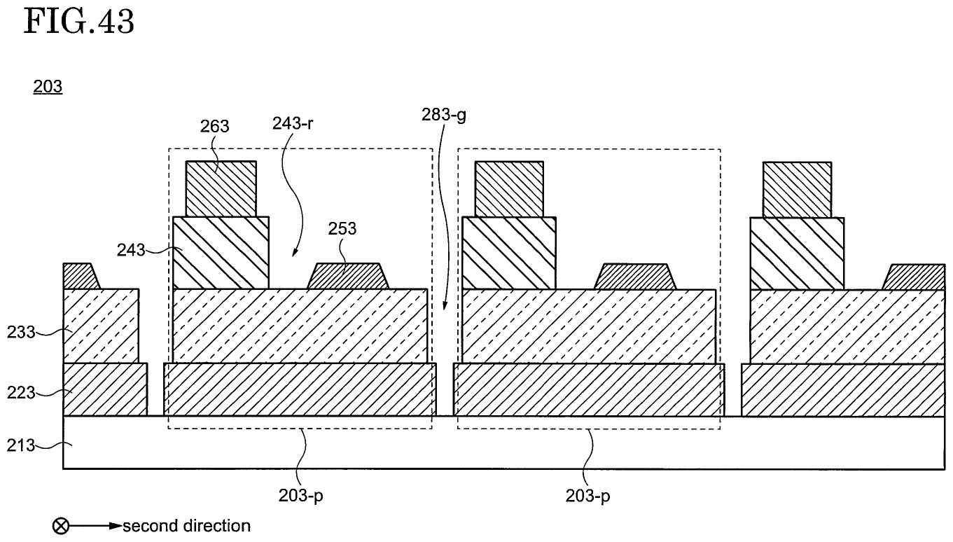

A light emitting device 203 according to an embodiment of the present invention is described with reference to FIG. 43. In addition, when a configuration of the light emitting device 203 is similar to the configurations of the light emitting devices 200 to 202, the description thereof may be omitted.

FIG. 43 is a schematic cross-sectional view showing a configuration of a light emitting device 203 according to an embodiment of the present invention. Specifically, FIG. 43 is a cross-sectional view of a pixel 203-p.

As shown in FIG. 43, the light emitting device 203 includes a substrate 213, an insulating alignment layer 223, a first nitride semiconductor layer 233, a second nitride semiconductor layer 243, a first electrode layer 253, and a second electrode layer 263.

The insulating alignment layer 223 is provided on the substrate 213. Further, the insulating alignment layer 223 is provided in an island shape in each of the plurality of pixels 203-p arranged in a matrix. The plurality of insulating alignment layers 223 are separated from each other by a groove portion 283-g in which the substrate 213 is exposed.

The first nitride semiconductor layer 233 and the second nitride semiconductor layer 243 are provided over the insulating alignment layer 223 in this order. Further, each of the first nitride semiconductor layer 233 and the second nitride semiconductor layer 243 is provided in an island shape in each of the plurality of pixels 203-p arranged in a matrix. The second nitride semiconductor layer 243 overlaps the first nitride semiconductor layer 233 and has a smaller area than the first nitride semiconductor layer 233 in a plan view. That is, the stack of the first nitride semiconductor layer 233 and the second nitride semiconductor layer 243 includes a recessed portion 243-r in which the first nitride semiconductor layer 233 is exposed. Further, the stacks of the first nitride semiconductor layer 233 and the second nitride semiconductor layer 243 are separated from each other by a groove portion 283-g.

The first electrode layer 253 is provided in the recessed portion 243-r and electrically connected to the first nitride semiconductor layer 233. Further, the first electrode layer 253 extends along the first direction and is provided commonly in a plurality of pixels 203-p arranged in the first direction. That is, the first electrode layer 253 is provided commonly in the plurality of pixels 203-p in one column. Therefore, in the first direction, the first electrode layer 253 is in contact with not only the top surface of the first nitride semiconductor layer 233 but also the side surface of the first nitride semiconductor layer 233.

The second electrode layer 263 is provided on the second nitride semiconductor layer 243. Further, the second electrode layer 263 is provided in an island shape in each of the plurality of pixels 203-p arranged in a matrix. In addition, the position of the second electrode layer 263 on the second nitride semiconductor layer 243 is not particularly limited thereto. Further, the size of the second electrode layer 263 is not particularly limited thereto.

Each of the plurality of pixels 203-p includes the first electrode layer 253, the first nitride semiconductor layer 233, the second nitride semiconductor layer 243, and the second electrode layer 263 for an LED. Here, one of the electrodes of the LED is the first electrode layer 253, and the other electrode of the LED is the second electrode layer 263. The first electrode layer 253 is provided commonly in the plurality of pixels 202-p arranged in the first direction. On the other hand, the second electrode layer 263 is provided in each of the plurality of pixels 203-p arranged in a matrix. In the light emitting device 203, a substrate on which a metal layer is formed, which is different from the substrate 213, is bonded to the substrate 213, and the plurality of electrode layers 263 are electrically connected to the metal layer. Therefore, in the light emitting device 203, light emission can be controlled using the plurality of pixels 203-p arranged in the first direction as one unit. In addition, the pixel 203-p may include the substrate 213 for convenience of explanation.

In the light emitting device 203, since the first nitride semiconductor layer 233 is provided on the insulating alignment layer 223, the crystallinity of the first nitride semiconductor layer 233 is improved. Further, since the second nitride semiconductor layer 243 is provided on the first nitride semiconductor layer 233 with improved crystallinity, the crystallinity of the second nitride semiconductor layer 243 including the light emitting layer is also improved. Therefore, the light emitting efficiency of the light emitting device 203 can be improved. Further, by providing the insulating alignment layer 223 on the substrate 213, it is possible to manufacture the plurality of light emitting devices 203 using a large-area amorphous substrate as the substrate 213.

Further, each of the first electrode layer 253 and the second electrode layer 263 may be provided in each of the plurality of pixels 203-p arranged in a matrix. That is, each of the first electrode layer 253 and the second electrode layer 263 may be provided in an island shape in one pixel 203-p. In this case, the first electrode layers 253 of two adjacent pixels 203-p are not electrically connected to each other. Similarly, the second electrode layers 263 of two adjacent pixels 203-p are not electrically connected to each other. In this case, for example, the light emitting device 203 can be used for an LED wafer on which LED chips are formed. Since the substrate 213 is an amorphous substrate such as a glass substrate, it can be easily cut out, and the cut out pixels 203-p can be used as LED chips.

### Modification 1 of Eighth Embodiment

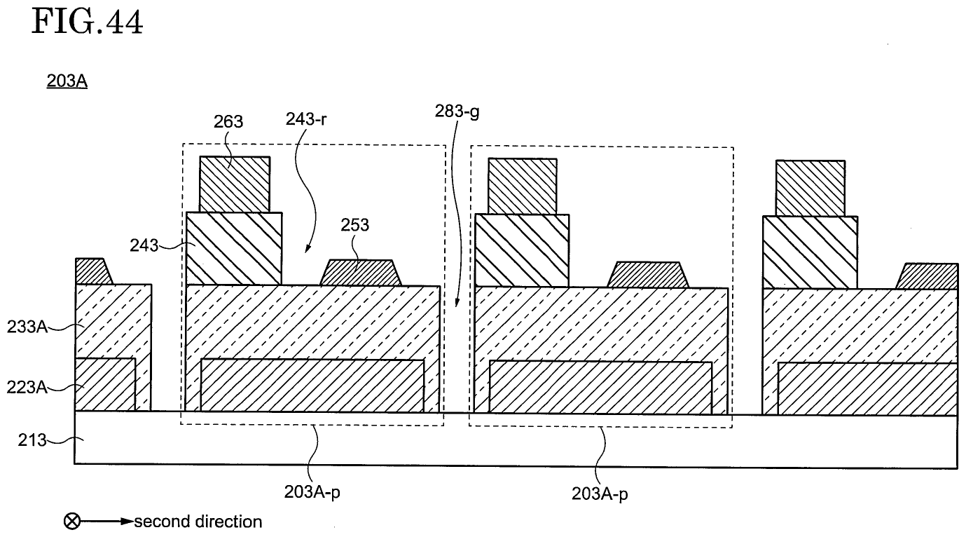

FIG. 44 is a schematic cross-sectional view showing a configuration of a light emitting device 203A according to an embodiment of the present invention. Specifically, FIG. 44 is a cross-sectional view of a pixel 203A-p. The light emitting device 203A is one modification of the light emitting device 203. Therefore, when the configuration of the light emitting device 203A is similar to the configuration of the light emitting device 203, the description thereof may be omitted.

As shown in FIG. 44, the light emitting device 203A includes the substrate 213, an insulating alignment layer 223A, a first nitride semiconductor layer 233A, the second nitride semiconductor layer 243, the first electrode layer 253, and the second electrode layer 263.

The insulating alignment layer 223A is also provided in an island shape in each of the pixels 203A-p arranged in a matrix, similar to the insulating alignment layer 223.

The first nitride semiconductor layer 233A and the second nitride semiconductor layer 243 are provided over the insulating alignment layer 223A in this order. Further, each of the first nitride semiconductor layer 233A and the second nitride semiconductor layer 243 is provided in an island shape in each of the plurality of pixels 203A-p arranged in a matrix. The second nitride semiconductor layer 243 overlaps the first nitride semiconductor layer 233A, and has a smaller area than the first nitride semiconductor layer 233A in a plan view. That is, the stack of the first nitride semiconductor layer 233A and the second nitride semiconductor layer 243 includes a recessed portion 243-r in which the first nitride semiconductor layer 233A is exposed. Further, the stacks of the first nitride semiconductor layers 233A and the second nitride semiconductor layers 243 are separated from each other by a groove portion 283-g. In addition, the side surfaces of the insulating alignment layer 223A are covered with the first nitride semiconductor layer 233A.

Each of the plurality of pixels 203A-p includes the first electrode layer 253, the first nitride semiconductor layer 233A, the second nitride semiconductor layer 243, and the second electrode layer 263 for an LED. Here, one of the electrodes of the LED is the first electrode layer 253, and the other electrode of the LED is the second electrode layer 263. The first electrode layer 253 is provided commonly in the plurality of pixels 202A-p arranged in the first direction. On the other hand, the second electrode layer 263 is provided in each of the plurality of pixels 203A-p arranged in a matrix.

In the light emitting device 203, a substrate on which a metal layer is formed, which is different from the substrate 213, is bonded to the substrate 213, and the plurality of electrode layers 263 are electrically connected to the metal layer. Therefore, in the light emitting device 203A, light emission can be controlled using the plurality of pixels 203-p arranged in the first direction as one unit.

Further, each of the first electrode layer 253 and the second electrode layer 263 may be provided in each of the plurality of pixels 203A-p arranged in a matrix. That is, each of the first electrode layer 253 and the second electrode layer 263 may be provided in an island shape in one pixel 203A-p. In this case, the first electrode layers 253 of two adjacent pixels 203A-p are not electrically connected to each other. Similarly, the second electrode layers 263 of two adjacent pixels 203A-p are also not electrically connected to each other. In this case, for example, the light emitting device 203A can be used for an LED wafer on which LED chips are formed. Since the substrate 213 is an amorphous substrate such as a glass substrate, it can be easily cut out, and the cut out pixels 203A-p can be used as LED chips.

### Ninth Embodiment

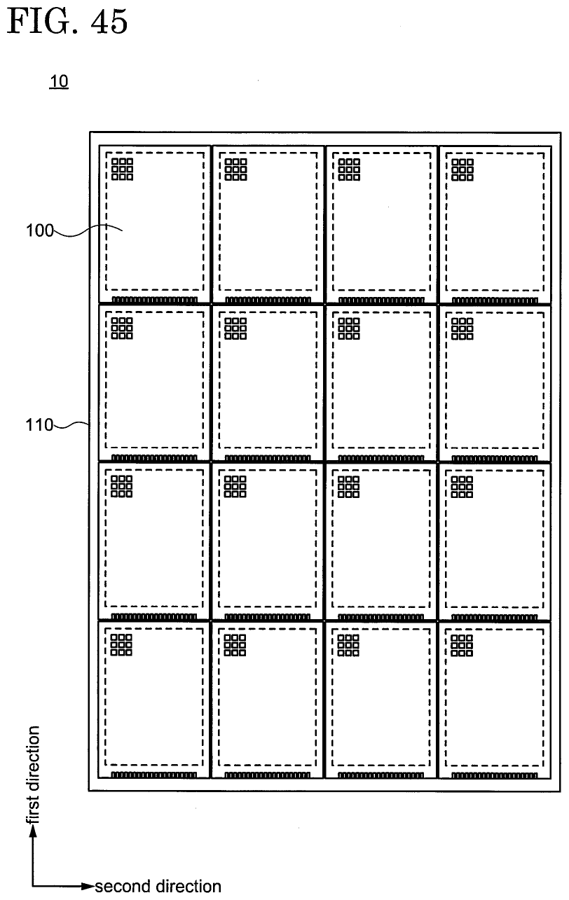

A light emitting device forming substrate 10 according to an embodiment of the present invention is described with reference to FIG. 45.

FIG. 45 is a schematic diagram showing a configuration of the light emitting device forming substrate 10 according to an embodiment of the present invention. The light emitting device forming substrate 10 includes the plurality of light emitting devices 100. That is, in the light emitting device forming substrate 10, the plurality of light emitting devices 100 are manufactured using one substrate 110. The substrate 110 is a so-called large-area substrate. In the light-emitting device forming substrate 10, the plurality of light-emitting devices 100 can be manufactured at once using a large-area substrate, so that the manufacturing cost of the light-emitting devices 100 can be suppressed.

In addition, although the light emitting device 100 described in the First Embodiment is described as an example, the light emitting devices (100A, 100B, 100C, 101, 101A, 101B, 101C, 101D, 101E, 102, 102A, 102B, 102C, 103, 103A, 200, 200A, 200B, 200C, 200D, 201, 201A, 201B, 201C, 202, 202A, 202B, 202C, 203, and 203A) described in other embodiments (including modifications) are also applied to the configuration of the present embodiment.

Each of the embodiments described above as an embodiment of the present invention can be appropriately combined and implemented as long as they do not contradict each other. Additions, deletions, or design changes of constituent elements, or additions, omissions, or changes to conditions of steps as appropriate based on the respective embodiments are also included within the scope of the present invention as long as the gist of the present invention is provided.

Other effects which differ from those brought about by each of the embodiments described above, but which are apparent from the description herein or which can be readily predicted by those skilled in the art, are naturally understood to be brought about by the present invention.

What is claimed is:

1. A light emitting device comprising:
a plurality of pixels arranged in a matrix in a first direction and in a second direction orthogonal to the first direction,
wherein each of the plurality of pixels arranged in a matrix comprises:
a substrate,
a conductive alignment layer over the substrate,
a first nitride semiconductor layer over the conductive alignment layer,
a second nitride semiconductor layer comprising a light emitting layer, over the first nitride semiconductor layer, and
an electrode layer over the second nitride semiconductor layer,
wherein the first nitride semiconductor layer and the second nitride semiconductor layer are provided in an island shape, and
wherein the plurality of pixels arranged in a matrix commonly comprises the substrate.

2. The light emitting device according to claim 1, wherein the conductive alignment layer is provided in common to the plurality of pixels arranged in a matrix.

3. The light emitting device according to claim 1, wherein the conductive alignment layer extends in the first direction and is provided commonly in the plurality of pixels arranged in the first direction.

4. The light emitting device according to claim 1, wherein the electrode layer is provided commonly in the plurality of pixels arranged in a matrix.

5. The light emitting device according to claim 1, wherein the electrode layer extends in the first direction and is provided commonly in the plurality of pixels arranged in the first direction.

6. The light emitting device according to claim 1, wherein the electrode layer extends in the second direction and is provided commonly in the plurality of pixels arranged in the second direction.

7. The light emitting device according to claim 1, wherein the conductive alignment layer comprises at least one selected from titanium and titanium nitride.

8. The light emitting device according to claim 1, wherein the substrate is amorphous.

9. The light emitting device according to claim 8,
wherein a first rib is provided between two adjacent first nitride semiconductor layers, and
a second rib is provided between two adjacent second nitride semiconductor layers.

10. A light emitting device comprising:
a plurality of pixels arranged in a matrix in a first direction and in a second direction orthogonal to the first direction,
wherein each of the plurality of pixels arranged in a matrix comprises:
a substrate,
an insulating alignment layer over the substrate,
a first nitride semiconductor layer over the insulating alignment layer,
a second nitride semiconductor layer comprising a light emitting layer, over the first nitride semiconductor layer,
a first electrode layer over the first nitride semiconductor layer, and
a second electrode layer over the second nitride semiconductor layer,
wherein the first nitride semiconductor layer and the second nitride semiconductor layer are provided in an island shape, and
wherein the plurality of pixels arranged in a matrix commonly comprises the substrate.

11. The light emitting device according to claim 10, wherein the insulating alignment layer is provided commonly in the plurality of pixels arranged in a matrix.

12. The light emitting device according to claim 10, wherein the insulating layer is provided in an island shape.

13. The light emitting device according to claim 10, wherein the second electrode layer is provided commonly in the plurality of pixels arranged in a matrix.

14. The light emitting device according to claim 10,
wherein the first electrode layer extends in the first direction and is provided commonly in the plurality of pixels arranged in the first direction, and
wherein the second electrode layer extends in the first direction and is provided commonly in the plurality of pixels arranged in the first direction.

15. The light emitting device according to claim 10,
wherein the first electrode layer extends in the first direction and is provided commonly in the plurality of pixels arranged in the first direction, and
wherein the second electrode layer extends in the second direction and is provided commonly in the plurality of pixels arranged in the second direction.

16. The light emitting device according to claim 10, wherein the insulating alignment layer comprises at least one selected from aluminum nitride and aluminum oxide.

17. The light emitting device according to claim 10, wherein the substrate is amorphous.

18. The light emitting device according to claim 17,
wherein a first rib is provided between two adjacent first nitride semiconductor layers, and
wherein a second rib is provided between two adjacent second nitride semiconductor layers.
